(19) United States
(12) Patent Application Publication
(10) Pub. No.: US 2025/0380479 A1
(43) Pub. Date: Dec. 11, 2025

(54) SEMICONDUCTING GRAPHENE AND PREPARATION METHOD THEREOF, FULL CARBON STRUCTURE AND PREPARATION METHOD THEREOF

(71) Applicant: TIANJIN UNIVERSITY, Tianjin (CN)

(72) Inventors: Lei MA, Tianjin (CN); Jian ZHAO, Tianjin (CN); Rui LI, Tianjin (CN); Peixuan JI, Tianjin (CN); Yaqi LI, Tianjin (CN)

(21) Appl. No.: 18/737,503

(22) Filed: Jun. 7, 2024

(51) Int. Cl. H01L 29/16; C01B 32/184; H01L 21/02

(52) U.S. Cl. CPC H10D 62/882; C01B 32/184; H01L 21/02301; H01L 21/02312; H10D 62/8325; C01B 2204/22; C01B 2204/32

(57) ABSTRACT

The present disclosure discloses a large single-crystal semiconducting graphene directly grown on the silicon face of a silicon carbide substrate and its preparation method, a semiconducting graphene-quasi-free standing graphene all-carbon structure and its preparation method, an ultra-large single-crystal quasi-free standing graphene and its preparation method; the semiconducting graphene is single-layered, uniformly grown, with crystal domain widths reaching up to 500 micrometers and lengths on the order of sub-millimeters, the room temperature mobility of the semiconducting graphene is capable of reaching 5000 cm²/(V·s). The semiconducting graphene can be direct prepared on an insulating substrate.

### TECHNICAL FIELD

The present disclosure relates to the technical field of semiconducting devices, in particular to a semiconducting graphene and its preparation method, as well as a full carbon structure and its preparation method.

### BACKGROUND ART

The rapid development of the semiconducting information industry has greatly changed human lifestyles, and this rapid development is achieved through the continuous miniaturization of electronic components. However, as Moore's Law approaches physical limits, the ceiling of silicon chip fabrication processes is within reach. In the post-Moore era, increasing the density of integrated circuits can be achieved through the miniaturization of device dimensions. Unfortunately, traditional materials face challenges in breaking their own limits, necessitating the further development of integrated circuits through the research and development of new materials, structures, and principles.

Importantly, carbon-based devices and all-carbon integrated circuits have gradually attracted attention from researchers worldwide in the early 21st century, positioning carbon-based electronics as a potential replacement for silicon-based CMOS technology. Carbon-based semiconducting offer advantages such as lower cost, lower power consumption, and higher efficiency compared to silicon-based materials. Furthermore, an all-carbon circuit exhibits strong tolerance to harsh environments, with excellent radiation resistance, meeting the diverse needs of different applications and scenarios compared to silicon-based circuits.

When it comes to new materials, two-dimensional materials, especially graphene, have gained increasing attention in recent years due to their atomic-level thickness and excellent performance. Graphene, composed of carbon atoms, is a two-dimensional material, and graphite is composed of multiple layers of graphene. Single-layer graphene can be extracted from graphite, and its electronic properties are similar to graphite. Graphene is a semi-metal, neither a metal nor a semiconducting, and can be described as a semiconducting without a bandgap (Wallace, 1947). The electronic properties of graphene are well understood, with high electron mobility and good conductivity, making it a promising two-dimensional electronic material with widespread applications in various fields.

However, graphene lacks a bandgap, making it unsuitable for traditional digital electronics that require switching through the application of an electric field, as in traditional semiconducting electronics like silicon. Despite various attempts to “modify” graphene to introduce a bandgap, such as creating narrow graphene ribbons (Han, 2010) or chemically modifying graphene properties (Elias, 2009), these modifications significantly degrade its electrical properties. So far, an effective method to produce semiconducting graphene with both semiconducting properties and high mobility has not been found.

In comparison to many other graphene growth methods, the use of single-crystal SiC substrates for epitaxial graphene growth can effectively avoid the introduction of defects such as wrinkles, cracks, and impurity contamination during the preparation of electronic devices. Importantly, epitaxial graphene processes are compatible with modern semiconducting processes, making it seemingly the only material available for the preparation of two-dimensional nanoelectronics devices based on current development trends. When silicon carbide is heated to above 1000° C. in an inert atmosphere, graphene forms on its surface. This form of graphene is called epitaxial graphene (van Bommel, 1975). It was found that the surface of hexagonal polycrystalline silicon carbide becomes graphitized when heated to above 1000° C. in a vacuum (van Bommel, 1975). Graphitization occurs because silicon sublimes from the surface at high temperatures, and the surface is covered with carbon atoms. At high temperatures, carbon atoms react to form silicon-carbon bonds covering the surface of silicon carbide. This form of graphene is called a buffer layer. Subsequent studies showed that due to the presence of silicon-carbon bonds, the buffer layer does not have the intrinsic electronic properties of graphene but behaves as an insulator (Emtsev, 2008). Further research using optimized high-temperature annealing methods, known as the controlled sublimation method (de Heer, 2011), to control the sublimation of silicon from the SiC surface showed that the electronic structure of this buffer layer indeed has a semiconducting bandgap (Nair, 2017). However, measurements of its electronic performance in electronic devices showed very low electron mobility (Turmaud, 2018) due to the disorder in the binding between the buffer layer and the SiC surface. Additionally, measurements indicated that a significant portion of the buffer layer is “contaminated” by graphene stripes “decorated” on the atomic steps of the SiC surface. Therefore, buffer layers produced by the CCS method (Nevius, 2015) are not suitable for electronics.

As the buffer layer grows, the silicon surface undergoes a bundling effect, resulting in a step-like morphology, alternately presenting a step-platform-step morphology. This will restrict the size of crystalline domains and affect their transport performance. The C-face of SiC generally grows multi-layer graphene due to the difficult control of Si sublimation rates. The Si-face can generally grow large-area single-layer epitaxial graphene, becoming the most widely studied platform. However, the mobility of Si-face single-layer graphene is lower than that of mechanically peeled graphene and CVD graphene, as the substrate and buffer layer have a decisive impact on the mobility of single-layer epitaxial graphene. Single-layer epitaxial graphene is heavily n-doped by the substrate and buffer layer, leading to low mobility. The buffer layer has a similar atomic arrangement to graphene, forming partial bonds between its carbon atoms and the silicon atoms of the substrate, thus lacking the intrinsic properties of graphene. However, quasi-free standing graphene can be obtained through hydrogen intercalation, greatly reducing coupling with the substrate, and the mobility almost does not change with temperature. Still, it is limited by step scattering and terrace width, and the development of single-crystal domain graphene has been stagnant.

Another key point is the inevitable influence of step bunching during the growth of Si-face epitaxial graphene. Epitaxial graphene tends to nucleate preferentially at steps, growing much faster than graphene on the terrace. Generally, the platform is covered with a single-layer graphene, while the steps are generally double-layer or triple-layer graphene. Importantly, steps and double-layer (or triple-layer) graphene scatter charge carriers, thus affecting the mobility of single-layer epitaxial graphene.

In summary, the development of epitaxial graphene faces several major challenges: 1) being heavily n-doped due to the influence of the substrate and buffer layer, resulting in low mobility; 2) mobility is temperature-dependent; 3) scattering by steps and double-layer (or triple-layer) graphene at steps affects graphene performance; 4) epitaxial graphene covering the platform is single-layer and uniform, but the platform width is generally within 10 μm due to growth process limitations, with a length not exceeding 50 μm; 5) single-crystal domain quasi-free standing graphene is greatly influenced by size.

### SUMMARY

The first objective of the present disclosure is to provide a large single-crystal semiconducting graphene and a preparation method thereof. This graphene can be directly grown on an insulating substrate, forming a single-layer, single-crystal semiconducting graphene with exceptionally large crystal domains and extremely high room temperature mobility. The semiconducting graphene can serve as a crucial component in electronic devices.

To achieve the aforementioned technical objectives, the present disclosure is implemented through the following technical solutions.

According to one aspect of the present disclosure, a large single-crystal semiconducting graphene directly grown on the silicon face of a silicon carbide substrate is provided, wherein the semiconducting graphene is single-layered, uniformly grown, with crystal domain widths reaching up to 500 micrometers and lengths on the order of sub-millimeters. The room temperature mobility of the semiconducting graphene is capable of reaching 5000 cm²/(V·s).

Furthermore, the semiconducting graphene exhibits a graphene lattice structure and forms bonds with the SiC substrate, resulting in a bandgap.

Additionally, the crystal domain width of the semiconducting graphene is greater than 200 micrometers.

Preferably, the silicon carbide substrate is of 6H, 4H, or 3C polytype.

According to another aspect of the present disclosure, a method for preparing the aforementioned large single-crystal semiconducting graphene is provided. The preparation method (Method A) includes the following steps:
S1, pre-treat several SiC substrates, wherein after pre-treatment, a carbon film is prepared on the C-face of one of the SiC substrates;
S2, stack the several SiC substrates and place them in a crucible with the Si-faces of the SiC substrates facing each other;
S3, anneal the crucible with the stacked SiC substrates under vacuum conditions to clean the SiC substrates;
S4, heat the crucible with the stacked SiC substrates in inert gas atmosphere;
S5, further heat the crucible with the stacked SiC substrates in inert gas atmosphere to grow semiconducting graphene, obtain semiconducting graphene on the SiC substrates.

Preferably, in step S1, the pre-treatment involves mechanical and chemical polishing of the SiC substrates, followed by ultrasonic cleaning and gas drying.

Furthermore, in step S1, the carbon film is selected from one of photoresist, PMMA, and amorphous carbon, prepared by any one of the following steps: high-temperature decomposition, physical vapor deposition, chemical deposition, or coating.

Preferably, the annealing temperature under vacuum conditions in step S3 ranges from 900° C. to 950° C., and the time ranges from 20 minutes to 30 minutes.

Preferably, the temperature for heating the SiC substrates in inert gas atmosphere in stepS4 ranges from 1250° C. to 1300° C., and the heating time ranges from 20 minutes to 30 minutes.

Preferably, the temperature for further heating in inert gas atmosphere in step S5 ranges from 1560° C. to 1700° C., and the time is 50 minutes to 600 minutes.

According to another aspect of the present disclosure, a method for preparing the aforementioned large single-crystal semiconducting graphene is provided. The preparation method (Method B) includes the following steps:
S1, pre-treat several SiC substrates;
S2, stack the several SiC substrates and place them in a crucible with the C-face of one SiC substrate facing the Si-face of the other;
S3, anneal the crucible with the stacked SiC substrates under vacuum conditions to clean the SiC substrates;
S4, heat the crucible with the stacked SiC substrates in inert gas atmosphere;
S5, further heat the crucible with the stacked SiC substrates in inert gas atmosphere to grow semiconducting graphene, obtain semiconducting graphene on one SiC substrate.

Preferably, in step S1, the pre-treatment involves mechanical and chemical polishing of the SiC substrates, followed by ultrasonic cleaning and gas drying.

Furthermore, in step S3, the annealing temperature under vacuum conditions preferably ranges from 900° C. to 950° C., and the time ranges from 20 minutes to 30 minutes.

Preferably, the temperature for heating the SiC substrates in inert gas atmosphere in stepS4 ranges from 1250° C. to 1300° C., and the heating time ranges from 20 minutes to 30 minutes.

Preferably, the temperature for further heating in inert gas atmosphere in step S5 ranges from 1560° C. to 1700° C., and the time ranges from 50 minutes to 600 minutes.

According to another aspect of the present disclosure, a method for preparing the aforementioned large single-crystal semiconducting graphene is provided. The preparation method (Method C) includes the following steps:
S1, pre-treat SiC substrates and place it in a modified crucible with the bottom outer surface of the crucible being flat;
S2, anneal the modified crucible with the stacked SiC substrate under vacuum conditions to clean the SiC substrate;
S3, heat the modified crucible with the stacked SiC substrate in inert gas atmosphere;
S4, further heat the modified crucible with the stacked SiC substrate in inert gas atmosphere to grow semiconducting graphene, obtain semiconducting graphene on the SiC substrate.

Preferably, in step S1, the pre-treatment involves mechanical and chemical polishing of the SiC substrate, followed by ultrasonic cleaning and gas drying.

Preferably, in step S3, the annealing temperature under vacuum conditions preferably ranges from 900° C. to 950° C., and the time ranges from 20 minutes to 30 minutes.

Preferably, the temperature for heating the SiC substrate in inert gas atmosphere in stepS4 ranges from 1250° C. to 1300° C., and the heating time ranges from 20 minutes to 30 minutes.

Preferably, the temperature for further heating in inert gas atmosphere in step S5 ranges from 1560° C. to 1700° C., and the time ranges from 50 minutes to 600 minutes.

The second objective of the present disclosure is to provide a semiconducting graphene-quasi-free standing graphene all-carbon structure and its preparation method. This structure allows the direct growth of single-layer single-crystal semiconducting graphene on an insulating substrate, exhibiting exceptionally large crystal domains and extremely high room temperature mobility. Simultaneously, through various means, the structure of semiconducting graphene-quasi-free standing graphene all-carbon is directly obtained, aiming to utilize this structure for the fabrication of high-performance all-carbon devices and integrated circuits.

A semiconducting graphene-quasi-free standing graphene all-carbon structure is provided, comprising a silicon carbide substrate, a Si-face of the substrate is prepared with semiconducting graphene and quasi-free standing graphene. Both the semiconducting graphene and quasi-free standing graphene are single-layered, forming a seamlessly overlapped continuous entity on the plane. The quasi-free standing graphene can serve as the electrode part, while the semiconducting graphene can function as the channel material.

According to another aspect of the present disclosure, a method for preparing the above-mentioned semiconducting graphene-quasi-free standing graphene all-carbon structure is provided. The preparation method includes the following steps:
S1, prepare the semiconducting graphene on the surface of the SiC substrate by either of Method A, Method B or Method C
S2, in a localized area of the semiconducting graphene obtained in step S1, prepare quasi-free standing graphene using one of the following methods: hydrogen intercalation, electron beam lithography, focused ion beam, laser-induced, or atomic force microscope tip heating.

Furthermore, when preparing the quasi-free standing graphene using hydrogen intercalation, the following steps are adopted:
S21, spin-coat photoresist on the surface of the semiconducting graphene;
S22, use photolithography to pattern the spun photoresist;
S23, deposit a dielectric layer on the patterned semiconducting graphene surface;
S24, peel off the photoresist-covered semiconducting graphene to obtain the patterned dielectric layer; partially cover the surface of the semiconducting graphene with the dielectric layer and leave the rest uncovered;
S25, heat the semiconducting graphene covered with the patterned dielectric layer in a hydrogen atmosphere to obtain the semiconducting graphene-quasi-free standing graphene all-carbon structure.

Furthermore, the dielectric layer is made of Al₂O₃, HfO₂, Y₂O₃, or SiO₂.

Furthermore, the deposition methods for the dielectric layer include atomic layer deposition, electron beam evaporation, and magnetron sputtering.

Preferably, in step S25, the hydrogen flow rate preferably ranges from 50 sccm to 100 sccm.

Preferably, in step S25, the heating temperature preferably ranges from 500° C. to 1100° C.

Preferably, in step S25, the heating time preferably ranges from 5 minutes to 60 minutes.

Additionally, when preparing quasi-free standing graphene using laser-induced methods, a laser power of 520-1500 mJ is used.

Additionally, when using atomic force microscopy tip heating, the tip is selected from one of atomic force microscopy tips, scanning tunneling microscopy tips, and multiple-probe scanning tips; and the heating temperature of the atomic force microscopy tip ranges from 500° C. to 900° C.

The third objective of the present disclosure is to provide a method for preparing ultra-large single-crystal quasi-free standing graphene. By first directly growing a single layer of single-crystal semiconducting graphene on an insulating substrate, which has ultra-large crystal domains and an extremely high room temperature mobility, the disclosure aims to obtain ultra-large single-crystal quasi-free standing graphene with high room temperature mobility and a centimeter-scale room temperature ultra-long ballistic mean free path using a hydrogen intercalation method.

To achieve the above technical objectives, the disclosure is implemented through the following technical solution.

An ultra-large single-crystal quasi-free standing graphene is provided. It includes a silicon carbide (SiC) substrate with a uniformly grown quasi-free standing graphene on the Si-face of the SiC substrate. The quasi-free standing graphene is a single layer, with crystal domain widths of up to 500 micrometers and lengths in the sub-centimeter range. The quasi-free standing graphene exhibits a centimeter-scale ballistic transport mean free path at room temperature.

Furthermore, the crystal domain width of the semiconducting graphene is greater than 200 micrometers, and the room temperature mobility of the quasi-free standing graphene can reach 3300 cm²/(V·s).

Furthermore, the quasi-free standing graphene is not bonded to the SiC substrate and exhibits semimetallic properties.

Additionally, to prepare the quasi-free standing graphene using hydrogen intercalation, the semiconducting graphene is heated in a hydrogen atmosphere at a temperature ranges from 900° C. to 1300° C. for a duration of 10 to 80 minutes.

Additionally, the hydrogen gas flow rate during hydrogen intercalation is preferably between 50 and 100 sccm.

The beneficial effects of the present disclosure are as follows:

Direct preparation on insulating substrate: the methods involve direct preparation on an insulating substrate, eliminating the need for additional transfer or modification steps, which simplify the process and ensure the semiconducting graphene being produced uniformly and as a single layer.

Key material for electronic devices: the prepared semiconducting graphene has optimal characteristics, with a maximum crystal domain width of 500 micrometers, length at the sub-centimeter level, and a room temperature mobility of at least 4500 cm²/(V·s) or higher. This makes the large single-crystal domain semiconducting graphene a crucial material for electronic devices.

Diverse SiC Substrate types: the SiC wafers used as substrates can be of various crystal types, including 6H, 4H, and 3C. Using low-cost commercial 4H SiC substrates further reduces production costs.

Simultaneous growth on multiple substrates: simultaneous preparation of semiconducting graphene on the Si surface of two SiC substrates increases production efficiency, enhancing the utilization of SiC wafers and further reducing costs.

Flexible carbon film source: the required carbon film can be from various sources, not limited to photoresists such as photoresist, PMMA (electron beam photoresist), and amorphous carbon. This flexibility allows factories to choose a carbon film preparation method based on their instrument and equipment setup.

Modified crucible for cost savings: modification of the crucible allows semiconducting graphene preparation without relying on a carbon film. This eliminates an additional step in industrial production, leading to significant cost savings.

In summary, the preparation methods of the disclosure provide a significant pathway for the industrial production of semiconducting graphene. They offer advantages such as simplified processes, utilization of diverse SiC substrates, increased production efficiency, and cost savings, making it a crucial advancement for the industrialization of semiconducting graphene production.

The present disclosure introduces a semiconducting graphene-quasi-free standing graphene all-carbon structure and its preparation method, achieving a seamlessly integrated structure. Key aspects include:

### Electrode and Channel Characteristics:

Quasi-free standing graphene has no interaction with the SiC substrate (interaction refers to bonding with the SiC substrate), preserving the intrinsic semi-metallic properties of graphene, serving as the electrode part.

Semiconducting graphene forms bonds with the SiC substrate, causing symmetry breaking and opening a bandgap, serving as the channel material.

The seamless connection between graphene as the electrode and graphene as the channel eliminates contact resistance, potentially solving challenges associated with the interface between metal electrodes and two-dimensional materials.

The obtained semiconducting graphene is uniformly grown as a single layer with an ultra-large single crystal domain (width exceeding 200 micrometers, optimally up to 500 micrometers).

Semiconducting graphene exhibits a high on/off ratio (up to 10,000), and quasi-free standing graphene demonstrates high mobility (up to 3000 cm²/(V·S)).

The advantages of semiconducting graphene and quasi-free standing graphene are combined, achieving a seamless connection between the electrode (quasi-free standing graphene) and the channel (semiconducting graphene), addressing technical challenges related to device performance influenced by “contact.”

Preparation method for ultra-large single crystal domain quasi-free standing graphene:

Direct growth on an insulating substrate results in single crystal dimensions expanding to 500 μm in width, reaching millimeter-level length, and growing uniformly without significant defects.

Hydrogen intercalation weakens the coupling effect of the substrate on graphene, producing ultra-large single crystal domain quasi-free standing graphene with a room temperature mobility of up to 3300 cm²/V·s, at least three times that of traditional epitaxial graphene.

### Application in Integrated Circuits (ICs):

Top-gate devices prepared with quasi-free standing graphene exhibit room temperature ultra-long ballistic transport performance, offering new prospects in the integrated circuit field.

The present disclosure has the potential to significantly reduce chip power consumption and heating issues, contributing to the development of the electronics field.

In summary, this disclosure presents a groundbreaking approach to the preparation of semiconducting graphene, showcasing a seamlessly integrated structure with promising applications in the field of electronics.

### BRIEF DESCRIPTION OF THE DRAWINGS

For the disclosure of large single-domain semiconducting graphene and its preparation method, the drawings attached thereto and corresponding implementations are as follows:

FIG. 1 is a schematic diagram of the growth of large single-crystal semiconducting graphene prepared using dual SiC substrates in Example 1;

FIG. 2 is a Scanning Electron Microscopy (SEM) image of large single-crystal semiconducting graphene prepared using dual SiC substrates in Example 1;

FIG. 3 is a Raman spectroscopy (Raman) image of large single-crystal semiconducting graphene prepared using dual SiC substrates in Example 1;

FIG. 4 is a Scanning Tunneling Spectroscopy (STS) image of large single-crystal semiconducting graphene prepared using dual SiC substrates in Example 1;

FIG. 5 is a mobility diagram of large single-crystal semiconducting graphene prepared using dual SiC substrates in Example 1;

FIG. 6 is a schematic diagram of the growth of large single-crystal semiconducting graphene prepared using a single SiC substrate in Example 2;

FIG. 7 is a Scanning Electron Microscopy (SEM) image of large single-crystal semiconducting graphene prepared using a single SiC substrate in Example 2;

FIG. 8 is a schematic diagram of the growth of large single-crystal semiconducting graphene prepared using a modified crucible in Example 3;

FIG. 9 is a Scanning Electron Microscopy (SEM) image of large single-crystal semiconducting graphene prepared using a modified crucible in Example 3;

FIG. 10 is a Scanning Electron Microscopy (SEM) image of large single-crystal semiconducting graphene prepared using dual SiC substrates in Example 4;

FIG. 11 is a mobility diagram of large single-crystal semiconducting graphene prepared using dual SiC substrates in Example 4;

FIG. 12 is a Scanning Electron Microscopy (SEM) image of large single-crystal semiconducting graphene prepared using dual SiC substrates in Example 5;

FIG. 13 is a mobility diagram of large single-crystal semiconducting graphene prepared using dual SiC substrates in Example 5;

FIG. 14 is a Scanning Electron Microscopy (SEM) image of large single-crystal semiconducting graphene prepared using dual SiC substrates in Example 6;

FIG. 15 is a mobility diagram of large single-crystal semiconducting graphene prepared using dual SiC substrates in Example 6;

FIG. 16 is a Scanning Electron Microscopy (SEM) image of large single-crystal semiconducting graphene prepared using dual SiC substrates in Example 7;

FIG. 17 is a Scanning Electron Microscopy (SEM) image of large single-crystal semiconducting graphene prepared using dual SiC substrates in Example 8;

FIG. 18 is a Scanning Electron Microscopy (SEM) image of large single-crystal semiconducting graphene prepared using dual SiC substrates in Example 9;

FIG. 19 is a Scanning Electron Microscopy (SEM) image of semiconducting graphene prepared using a conventional crucible in Example 10;

FIG. 20 shows the SEM diagram of the sample prepared by example 11 using a two-piece SiC substrate.

FIG. 21 shows the SEM diagram of the sample prepared by Example 12 using a two-piece SiC substrate.

FIG. 22 shows the SEM diagram of the sample prepared by Example 13 using a two-piece SiC substrate.

FIG. 23 shows the SEM image of the sample prepared by Example 14 using a two-piece SiC substrate.

FIG. 24 shows the SEM image of the sample obtained in Example 15.

FIG. 25 shows the SEM image of the sample obtained in Example 16.

FIG. 26 shows the SEM image of the sample obtained in Example 17.

FIG. 27 shows the SEM image of the sample obtained in Example 18.

In the above diagrams:
100—conventional graphite crucible, 300—modified graphite crucible, 101/201—SiC substrate upper piece, 102/202—SiC substrate lower piece, 301—SiC substrate, 103—Carbon film, 104/204/304—gas atmosphere, 105/205—gas exchange port.

For a semiconducting graphene-quasi-free standing graphene-all-carbon structure of the present disclosure and a preparation method thereof, the drawings attached thereto and corresponding implementations are as follows:

FIG. 28 is a schematic diagram of the structure of quasi-free standing graphene-semiconducting graphene prepared in Example 19 of the present disclosure.

FIG. 29 shows a Raman spectrum of the structure of quasi-free standing graphene-semiconducting graphene prepared in Example 19 of the present disclosure.

FIG. 30 is a Scanning Electron Microscopy (SEM) image of the structure of quasi-free standing graphene-semiconducting graphene prepared in Example 19 of the present disclosure.

FIG. 31 is a graphene prepared in Example 19 of the present disclosure.

FIG. 32 is a Scanning Electron Microscopy (SEM) image of the structure of quasi-free standing graphene-semiconducting graphene prepared in Example 32 of the present disclosure.

FIG. 33 is a Scanning Electron Microscopy (SEM) image of the structure of quasi-free standing graphene-semiconducting graphene prepared in Example 32 of the present disclosure.

For a super-large single-crystal domain quasi-free standing graphene of the disclosure and a preparation method thereof, the drawings attached thereto and corresponding implementations are as follows:

FIG. 34 is the Raman spectrum of random point characterization of the sample prepared by Example 42.

FIG. 35 shows the temperature relation of the transfer characteristic curve of the sample prepared in Example 42, showing the ballistic transport free path at room temperature in the order of centimeters.

FIG. 36 shows the SEM diagram of the sample prepared by Example 43.

FIGS. 37A, 37B, and 37C show the AFM morphology and friction force (LFM) of the sample prepared in Example 44. FIG. 37A is a schematic diagram of AFM scan sample; FIG. 37B is a topography, illustrated with random line scan data; and FIG. 37C is a friction force (LFM), illustrated with random line scan data.

FIG. 38 shows the relationship between the mobility and temperature of the sample prepared in Example 45.

FIG. 39 is a schematic diagram of the growth process of quasi-free standing graphene in the present disclosure.

FIG. 40 is an atomic structure schematic diagram (side view) of quasi-free standing graphene in the present disclosure, where yellow solid spheres represent Si atoms, gray solid spheres represent C atoms, and blue solid spheres represent H atoms.
Wherein, 100,200,300: graphite crucible; 101: SiC substrate upper piece; 102: SiC substrate lower piece; 104, 304: gas environment; 105: gas exchange port; 201: SiC substrate upper piece; 301: source wafer SiC substrate.

### DETAILED DESCRIPTION OF THE PRESENT DISCLOSURE

The present disclosure will be further described in detail with reference to the drawings and specific examples. The following detailed descriptions of specific examples further elaborate on this disclosure. These examples are intended to give those skilled in the art a more comprehensive understanding of the disclosure, without limiting the scope of the disclosure in any way.

For the disclosure of large single-domain semiconducting graphene and its preparation method, the implementation is as follows:

Example 1 The semiconducting graphene is directly grown on the Si surface of a SiC substrate, with the specific steps as follows:

### Selection of SiC Wafers:

Choose two silicon carbide (SiC) wafers, named SiC substrate A and SiC substrate B.

Both SiC substrate A and SiC substrate B are chemically mechanically polished (CMP) to remove paraffin and thoroughly cleaned.

### Ultrasonic Cleaning:

Substrate A and substrate B are ultrasonically cleaned in acetone, anhydrous ethanol, and deionized water for 15-30 minutes, followed by drying with N₂.

### Carbon Film Coating:

A carbon film is applied to the C-face of SiC wafer A. The carbon film can be prepared using methods like high-temperature decomposition, spin-coating, physical vapor deposition, or chemical plating. SiC wafer B is not coated with a carbon film.

### Arrangement in Graphite Crucible:

Place the carbon-coated SiC wafer A and the uncoated SiC wafer B in a conventional graphite crucible. Specifically, stack the bottom SiC wafer A with its Si-face facing the Si-face of the top SiC wafer B.

### Induction Heating Furnace Process:

Place the graphite crucible containing SiC wafers A and B into an induction heating furnace: a. first stage: maintain in a vacuum environment at 900-950° C. for 20-30 minutes; b. second stage: introduce a flow of 400 sccm Ar gas, maintain a constant temperature of 1250-1300° C. for 20-30 minutes; c. third stage: continue with 400 sccm flowing Ar gas, maintain at 1605° C. for 95 minutes.

### Cooling and Sample Retrieval:

Allow the furnace to cool and retrieve the sample.

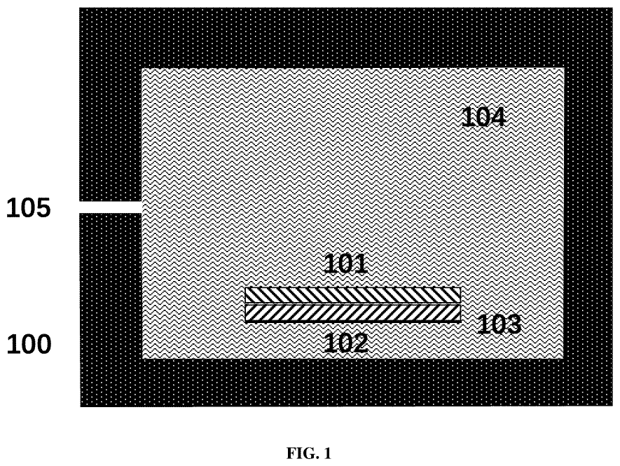

### Growth Illustration (FIG. 1):

The growth process includes a conventional graphite crucible 100, which can be heated resistively by running a current through the crucible walls or by induction heating using radio frequency. The conventional graphite crucible 100 has a gas exchange port 105, allowing it to be evacuated to high vacuum (pressure P=10⁻⁵ Torr) and filled with an inert gas, such as an Ar gas environment 104, at a pressure of up to 1 bar. The two SiC substrates are placed inside the conventional graphite crucible 100, with the SiC substrate lower piece 102 acting as the source and the SiC substrate upper piece 101 as the seed. The carbon film 103 is located beneath the SiC substrate lower piece 102, and the system is designed so that the temperature of the SiC substrate lower piece 102 is slightly higher than that of the SiC substrate upper piece 101. The conventional graphite crucible 100 is heated in several stages up to about 1605° C. from room temperature.

### Preferred Heating Mode:

In the first stage, the temperature is raised from room temperature to 900-950° C. under vacuum at a rate of 2° C. per second, maintaining at 900-950° C. for 20-30 minutes. The purpose of this stage is to clean the surfaces of the source and seed.

In the second stage, the pressure in the chamber of the graphite crucible 100 is increased to 1 Bar of Ar gas, and the temperature is raised to 1250-1300° C. at about 1° C. per second, maintaining this temperature for 20-30 minutes. In the second stage, well-developed, atomically flat, regularly spaced micrometer steps are formed on the seed layer.

In the third stage, the temperature is raised at a rate of 1° C. per second to about 1605° C., maintaining this temperature for 95 minutes, and then cooled to room temperature at about 1° C. per second.

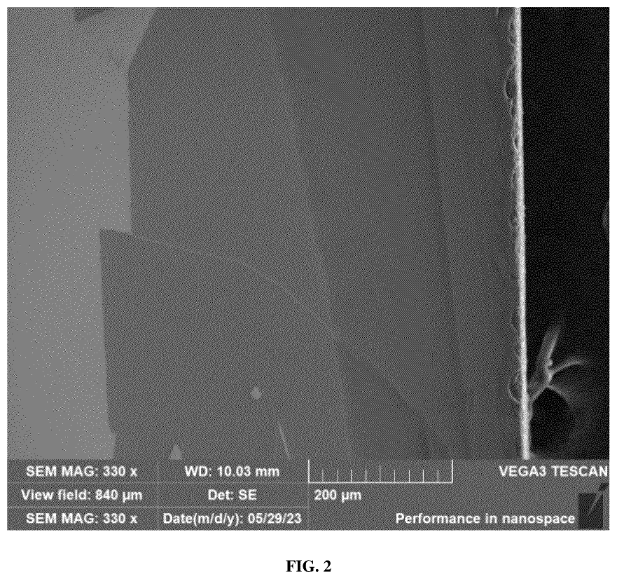

### SEM Imaging (FIG. 2):

The SEM image of the sample prepared using a double SiC substrate in Example 1 shows semiconducting graphene domains with a width of up to 500 μm and lengths reaching the sub-centimeter scale.

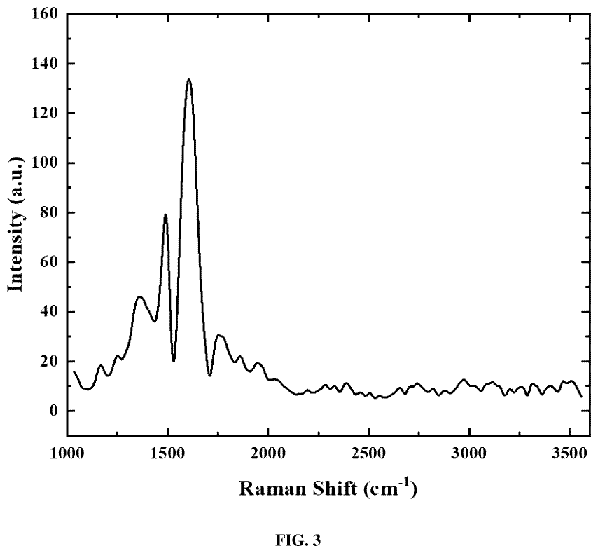

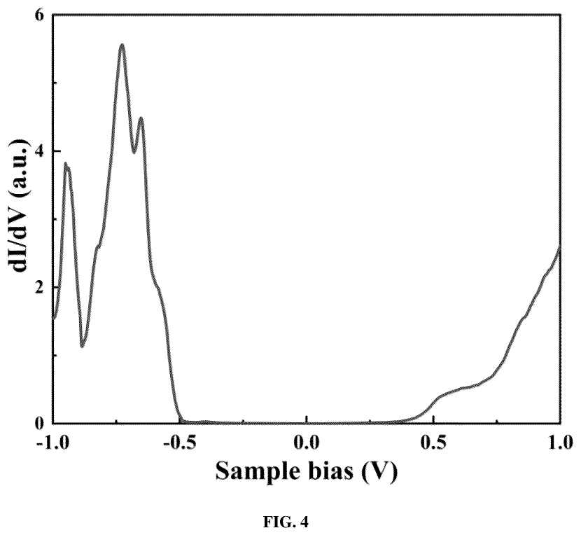

### Raman and STS Imaging (FIGS. 3 and 4):

The Raman and STS images of the sample from Example 1 show that the sample consists of single-domain, single-layer semiconducting graphene. The sample has a graphene lattice structure, is partially bonded to the SiC substrate, and possesses a band gap.

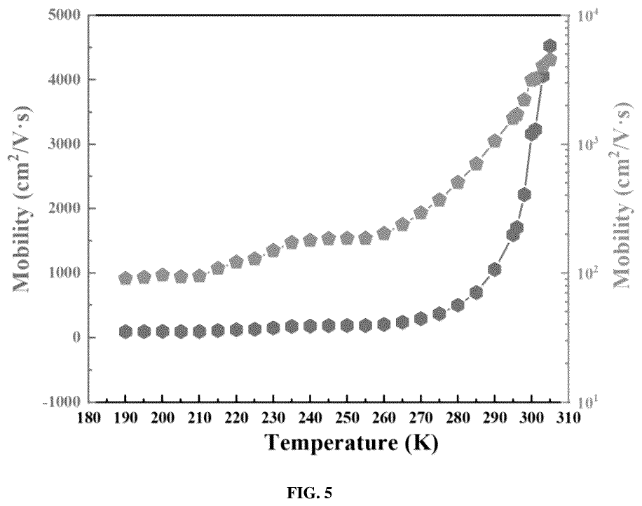

### Mobility Chart (FIG. 5):

As shown in FIG. 5, the room temperature mobility of the sample from Example 1 can exceed 4500 cm²/(V·s)

Example 2: Direct Growth of semiconducting graphene on Si-Faced Sic Substrate

### Selection and Preparation of SiC Substrates:

Two silicon carbide (SiC) wafers are selected, referred to as SiC substrate A and SiC substrate B.

Both substrates undergo Chemical Mechanical Polishing (CMP) to remove any paraffin and are thoroughly cleaned.

### Cleaning Process:

SiC substrates A and B are ultrasonically treated in acetone, anhydrous ethanol, and deionized water for 15-30 minutes, followed by drying with N₂.

### Arrangement in Graphite Crucible:

SiC wafer A and SiC wafer B are placed in a conventional graphite crucible. Specifically, the carbon face (C-face) of SiC wafer A is positioned opposite the silicon face (Si-face) of SiC wafer B.

### Induction Heating Furnace Procedure:

The graphite crucible containing the stacked SiC substrates is placed in an induction heating furnace and undergoes three stages: a. first stage: maintain in a vacuum environment at 900-950° C. for 20-30 minutes; b. second stage: introduce a flow of 400 sccm Ar gas, maintaining a constant temperature of 1250-1300° C. for 20-30 minutes; c. third stage: continue with 400 sccm flowing Ar gas, maintaining at 1610° C. for 105 minutes.

### Cooling and Sample Retrieval:

The furnace is cooled down, and the sample is retrieved.

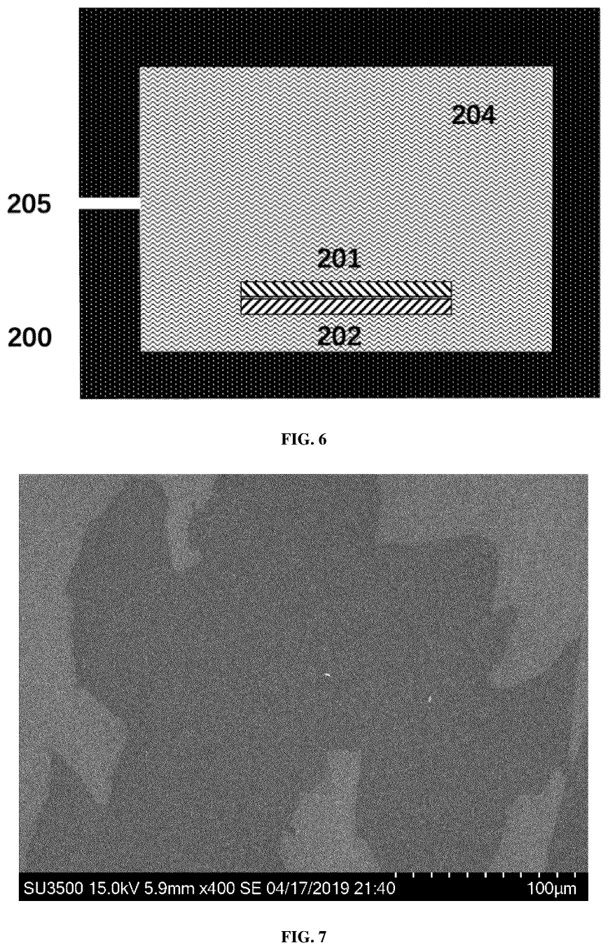

### Growth Illustration (FIG. 6):

Example 2 demonstrates growth without the use of a carbon film, requiring two specifically arranged SiC substrates, i.e., Si-face against C-face, to prepare semiconducting graphene.

Required instrument and equipment setup includes a graphite crucible 200 capable of resistive heating via current flow through the graphite crucible walls or induction heating using radio frequency.

The graphite crucible 200 features a gas exchange port 205 to achieve high vacuum (pressure p=10⁻⁵ Torr) and fill with an inert gas atmosphere, such as an Ar gas atmosphere 204 at a pressure up to 1 bar.

Two SiC wafers are placed inside the graphite crucible 200, with the SiC substrate lower piece 202 as the source and the SiC substrate upper piece 201 as the seed. The graphite crucible 200 is heated in several stages up to about 1610° C. from room temperature.

### Preferred Heating Mode:

In the first stage, the temperature is raised from room temperature to 900-950° C. under vacuum at a rate of 2° C. per second, maintaining at 900-950° C. for 20-30 minutes. The purpose of this stage is to clean the surfaces of the source and seed.

In the second stage, the pressure in the chamber of graphite crucible 200 is increased to 1 bar with Ar gas, and the temperature is raised to 1250-1300° C. at approximately 1° C. per second, maintaining for 20-30 minutes. This stage facilitates the formation of well-developed, atomically flat, regularly spaced micrometer steps on the seed layer.

In the third stage, the temperature is increased at a rate of 2° C. per second to about 1610° C., maintaining for 105 minutes at 1610° C., followed by cooling to room temperature at approximately 2° C. per second.

### SEM Imaging (FIG. 7):

The SEM image of the sample prepared using a single SiC substrate in Example 2 reveals the formation of single-layer semiconducting graphene domains exceeding 200 μm in width.

Example 3 Direct growth of semiconducting graphene on the Si surface of a SiC substrate, with the following specific steps:

### Selection and Preparation of SiC Wafer:

Choose a silicon carbide (SiC) wafer, and subject it to Chemical Mechanical Polishing (CMP) to remove paraffin and thoroughly clean it.

### Ultrasonic Cleaning:

Clean the SiC substrate in acetone, anhydrous ethanol, and deionized water using ultrasonics for 15-30 minutes, followed by drying with N₂.

### Placement in a Modified Graphite Crucible:

Place the SiC wafer in a modified graphite crucible, where the bottom outer surface of the crucible is modified from a curved to a flat surface.

### Induction Heating Furnace Process:

Place the modified graphite crucible containing the SiC substrate into an induction heating furnace: a. first stage: maintain in a vacuum environment at 900-950° C. for 20-30 minutes; b. second stage: introduce a flow of 400 sccm Ar gas, maintaining a constant temperature of 1250-1300° C. for 20-30 minutes; c. third stage: continue with 400 sccm flowing Ar gas, maintaining at 1700° C. for 80 minutes.

### Cooling and Sample Retrieval:

Allow the furnace to cool and retrieve the sample.

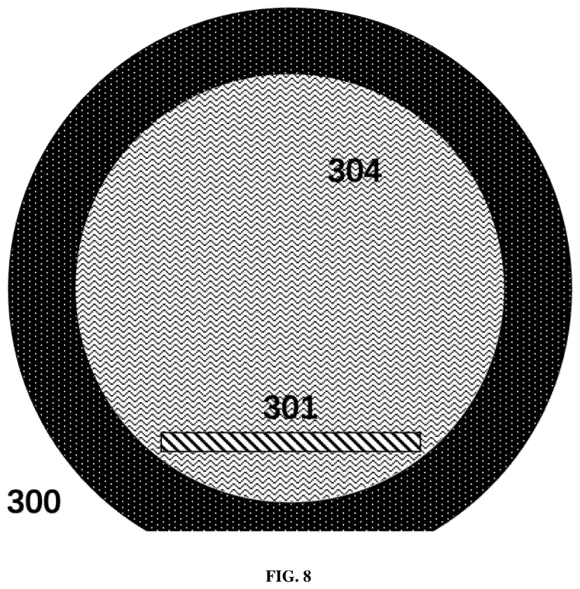

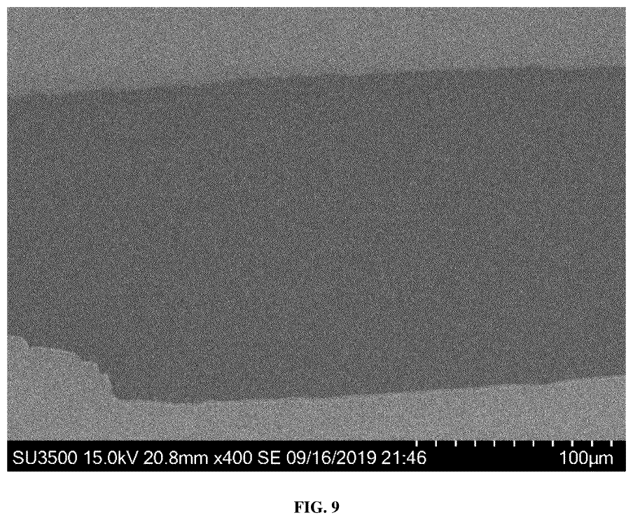

### Growth Illustration (FIG. 8):

Example 3 is carried out in the modified graphite crucible 300 with an Ar gas atmosphere 304. The modified graphite crucible 300 has its bottom outer surface changed from a curved to a flat surface. This causes the induced eddy currents at the flat surface to differ from other parts, resulting in different temperatures. In this example, the edge of the source wafer SiC substrate 301 directly contacts the walls of the modified graphite crucible 300, leading to inconsistent temperatures between the edge and the center of the substrate.

### SEM Imaging (FIG. 9):

The SEM image from Example 3 using a single SiC substrate shows the formation of large single-domain, single-layer semiconducting graphene domains exceeding 200 μm in width.

Example 4 semiconducting graphene is directly grown on the Si face of a SiC substrate using the preparation method from Example 1, with the only difference being in step (5), where the third stage heating time is 50 minutes.

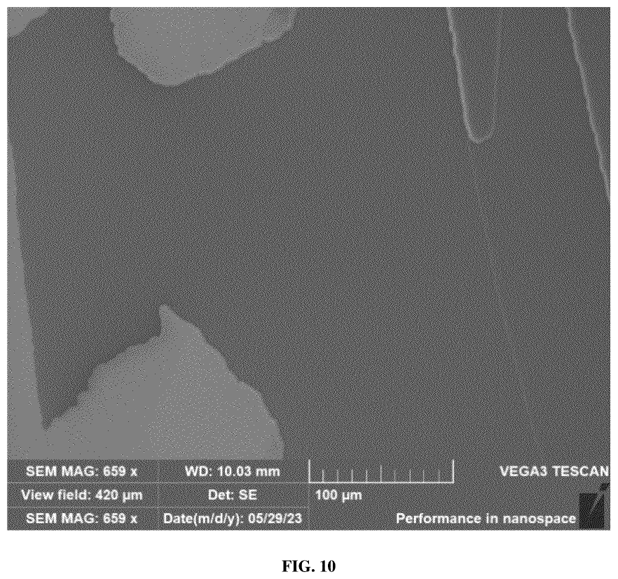

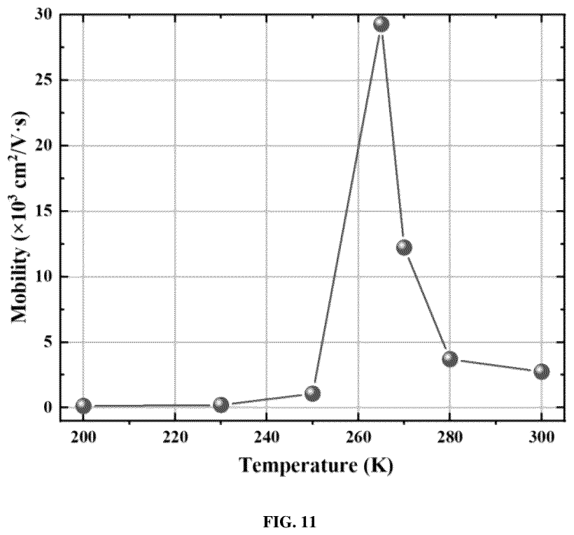

### SEM Imaging (FIG. 10):

The SEM image from Example 4 using a double SiC substrate shows semiconducting graphene domains with widths exceeding 200 μm.

### Mobility Chart (FIG. 11):

The mobility chart from Example 4 using a double SiC substrate shows a mobility exceeding 4500 cm²/(V·s).

Example 5 semiconducting graphene is directly grown on the Si face of a SiC substrate using the preparation method from Example 1, with the only difference being in step (5), where the third stage heating temperature is 1580° C.

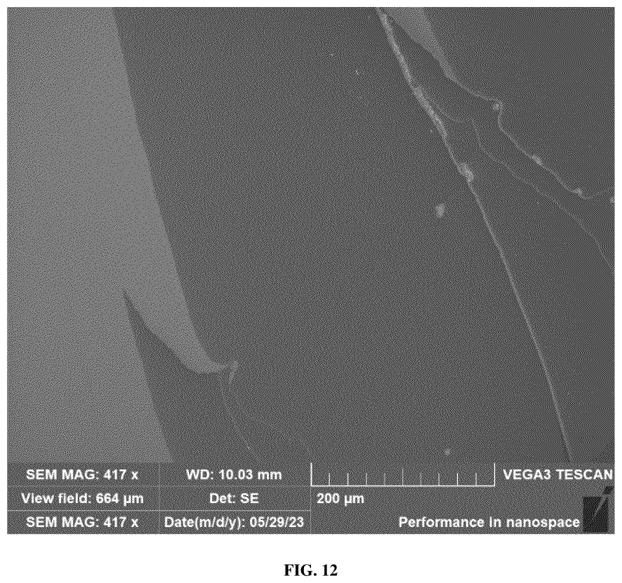

### SEM Imaging (FIG. 12):

The SEM image from Example 5 using a double SiC substrate shows semiconducting graphene domains with widths exceeding 200 μm.

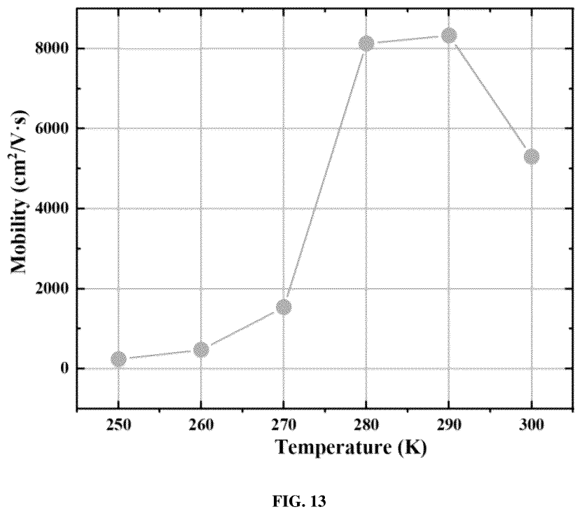

### Mobility Chart (FIG. 13):

The mobility chart from Example 3 using a double SiC substrate shows a mobility exceeding 4500 cm²/(V·s).

Example 6 semiconducting graphene is directly grown on the Si face of a SiC substrate using the preparation method from Example 1, with the only difference being in step (5), where the third stage heating temperature is 1560° C.

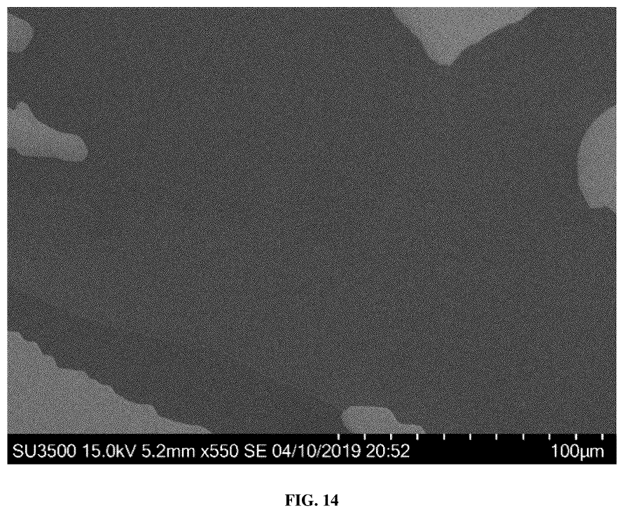

### SEM Imaging (FIG. 14):

The SEM image from Example 6 using a double SiC substrate shows semiconducting graphene domains with widths exceeding 200 μm.

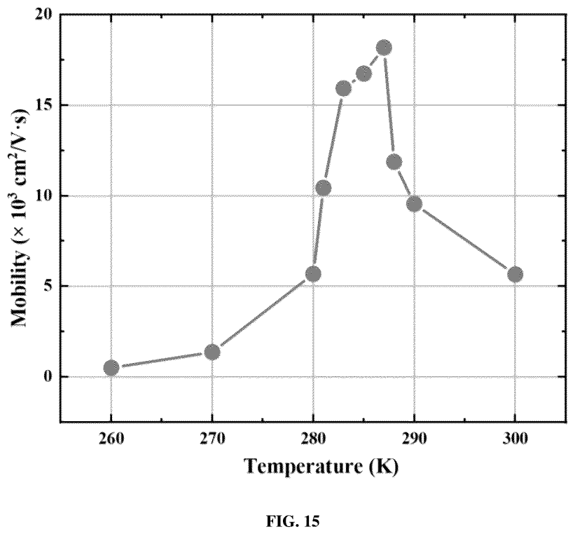

### Mobility Chart (FIG. 15):

The mobility chart from Example 6 using a double SiC substrate shows a mobility exceeding 4500 cm²/(V·s).

Example 7 semiconducting graphene is directly grown on the Si face of a SiC substrate using the preparation method from Example 1, with the only difference being in step (3), where amorphous carbon is sputtered.

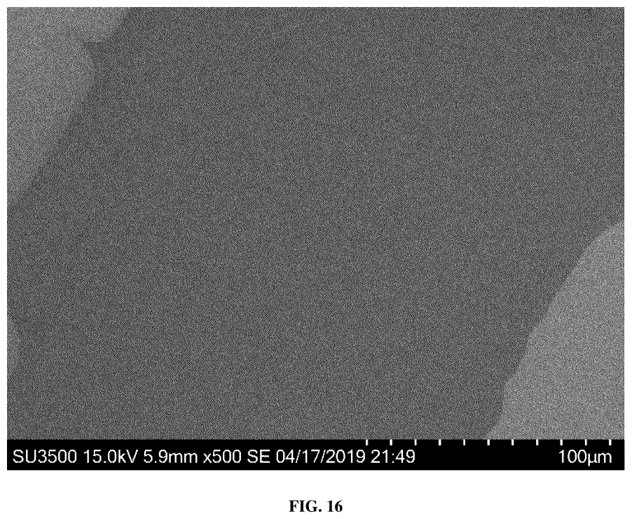

### SEM Imaging (FIG. 16):

The SEM image from Example 7 using a double SiC substrate shows semiconducting graphene domains with widths exceeding 200 μm.

Example 8 semiconducting graphene is directly grown on the Si face of a SiC substrate using the preparation method from Example 1, with the only difference being in step (5), where the Ar gas flow rate in the second and third stages is 50 sccm.

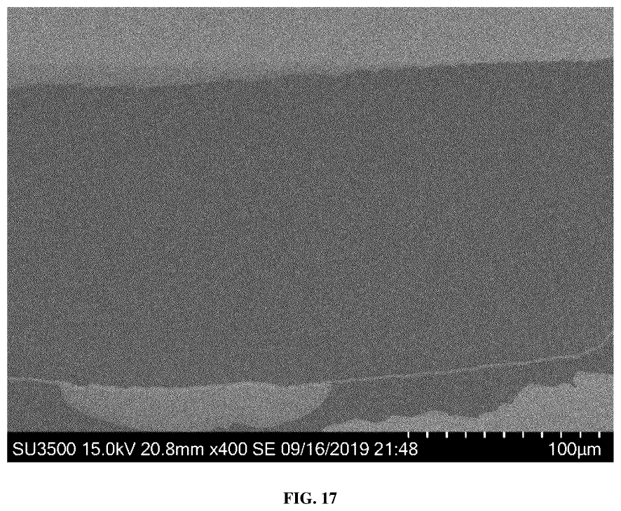

### SEM Imaging (FIG. 17):

The SEM image from Example 8 using a double SiC substrate shows semiconducting graphene domains with widths exceeding 200 μm.

Example 9 semiconducting graphene is directly grown on the Si face of a SiC substrate using the preparation method from Example 1, with the only difference being in step (5), where the Ar gas flow rate in the second and third stages is 800 sccm.

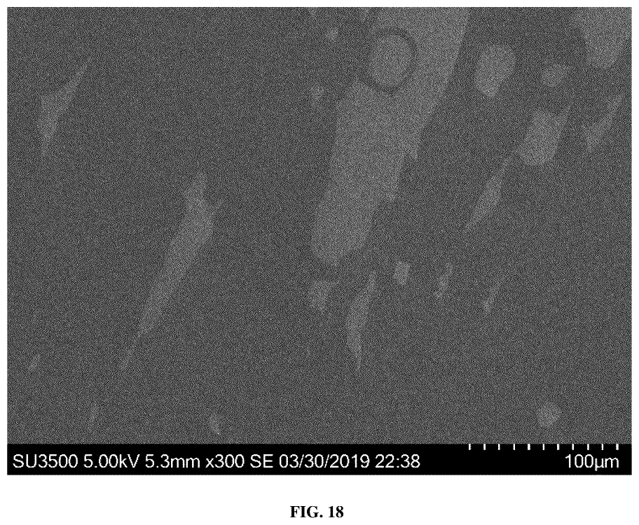

### SEM Imaging (FIG. 18):

The SEM image from Example 9 using a double SiC substrate shows semiconducting graphene domains with widths exceeding 200 μm.

Example 10 semiconducting graphene is directly grown on the Si face of a SiC substrate using the preparation method from Example 3, with the only difference being the use of an unmodified, conventional graphite crucible.

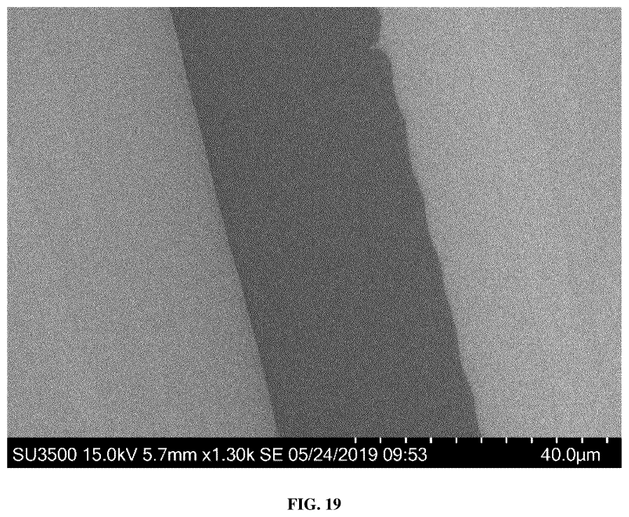

### SEM Imaging (FIG. 19):

The SEM image from Example 10 using a double SiC substrate shows semiconducting graphene domains with widths of only about 30 μm.

Example 11 Semiconducting graphene is grown directly on the Si surface of the SiC substrate in the following steps:
S1, select two silicon carbide wafers, respectively called silicon carbide substrate A and silicon carbide substrate B; Chemical mechanical polishing (CMP) of silicon carbide substrate A and silicon carbide substrate B, paraffin removal and thorough cleaning;
S2, silicon carbide substrate A and silicon carbide substrate B were ultrasonic in acetone, anhydrous ethanol, deionized water for 15-30 min, and then dried with N₂;
S3, the Si surface of silicon carbide A is covered with carbon film, and silicon carbide B is not coated with carbon film; the carbon film can be prepared by high temperature decomposition, spin coating, physical evaporation and electroless plating.
S4, the silicon carbide sheet A coated with carbon film and the silicon carbide sheet B not coated with carbon film are put into the conventional graphite crucible; Specifically, the bottom silicon carbide wafer A is stacked with the top silicon carbide wafer B, and the C face of silicon carbide wafer A is opposite to the Si face of silicon carbide wafer B;
S5, put the graphite crucible equipped with silicon carbide sheet A and silicon carbide sheet B into the induction heating furnace:
S51, maintain the equipped graphite crucible in a vacuum environment at 900° C. for 25 min;
S52, introduce with 1 bar Ar flow, maintaining at 1300° C. constant temperature for 25 min;
S53, introduce with 400 bar Ar flow, maintaining at 1600° C. for 95 min;
S6, the sample was obtained by furnace cooling.

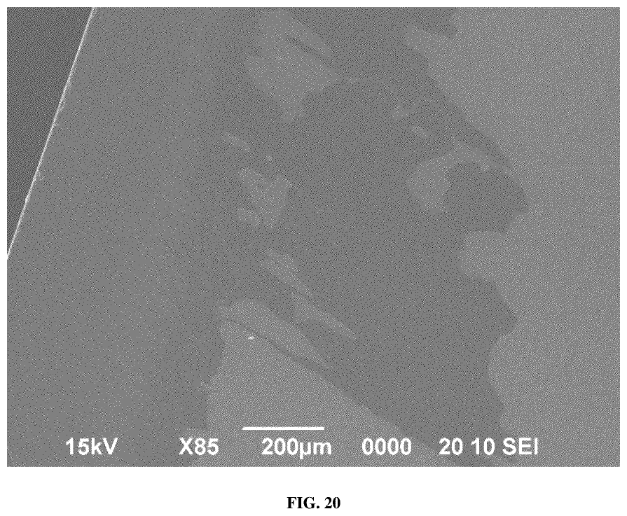

FIG. 20 is the SEM diagram of the sample prepared by example 11 using a two-piece SiC substrate. As can be seen from FIG. 20, the crystal domain width of semiconducting graphene exceeds 200 μm.

Example 12 Semiconducting graphene is grown directly on the Si surface of a SiC substrate using the preparation method of Example 1, the difference being only that the gas in the second and third stages of step S5 is helium.

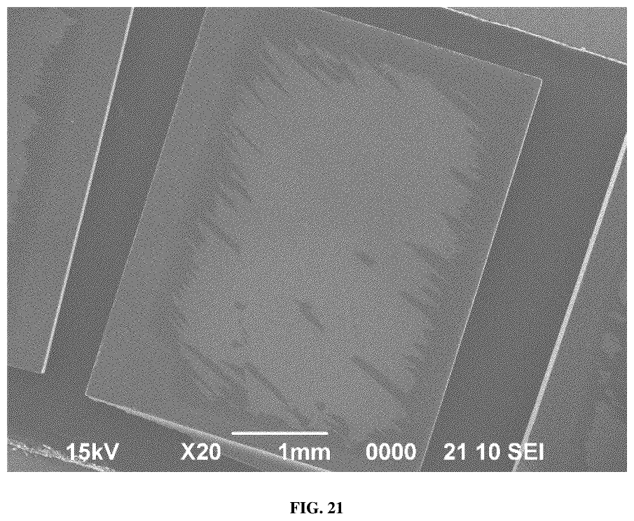

FIG. 21 shows the SEM image of the sample prepared by Example 12 using a two-piece SiC substrate. As can be seen from FIG. 20, the crystal domain width of semiconducting graphene exceeds 200 μm.

Example 13 Semiconducting graphene is grown directly on the Si surface of a SiC substrate using the preparation method of Example 1, with the only difference being that the gases in the second and third stages of step S5 are neon.

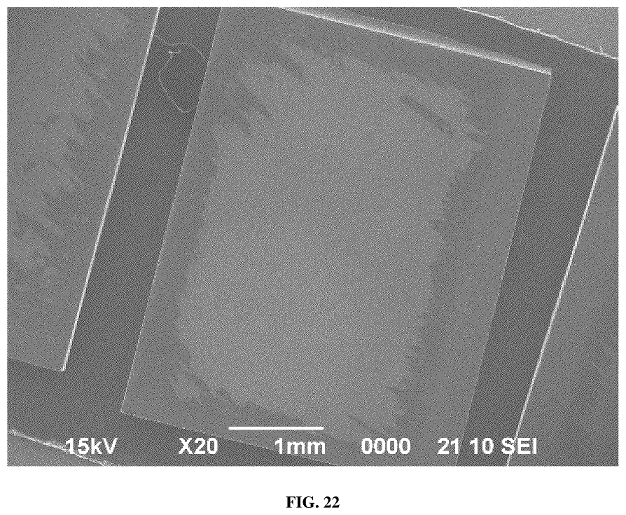

FIG. 22 shows the SEM image of the sample prepared by example 13 using a two-piece SiC substrate. As can be seen from FIG. 22, the crystal domain width of semiconducting graphene exceeds 200 μm.

Example 14 Semiconducting graphene is grown directly on the Si surface of a SiC substrate using the preparation method of Example 1, the difference being only that the gas in the second and third stages of step S5 is nitrogen.

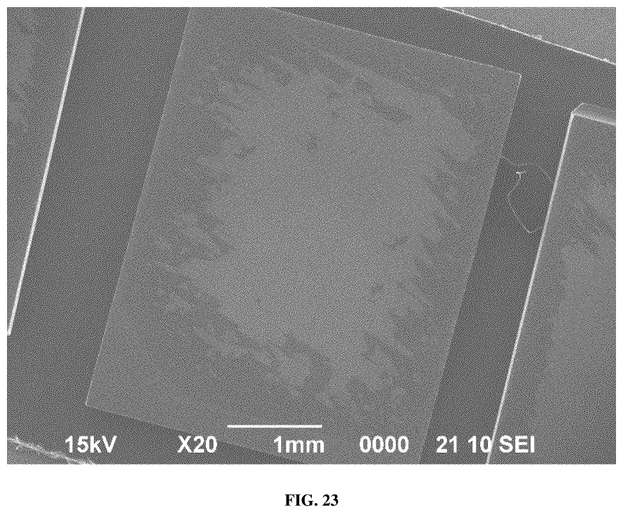

FIG. 23 shows the SEM image of the sample prepared by example 14 using a two-piece SiC substrate. As can be seen from FIG. 23, the crystal domain width of semiconducting graphene exceeds 200 μm.

Example 15 Semiconducting graphene is grown directly on the Si surface of the SiC substrate using the preparation method of Example 2, the difference being only that three SiC wafers are stacked in the crucible, 6H-4HN-6H from top to bottom.

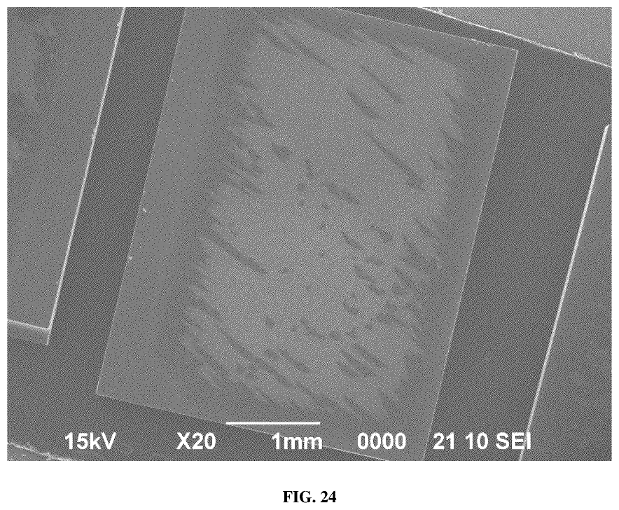

FIG. 24 is the SEM image of the sample obtained in example 15. As can be seen from FIG. 24, the crystal domain width of semiconducting graphene exceeds 200 μm.

Example 16 Semiconducting graphene is grown directly on the Si surface of the SiC substrate using the preparation method of Example 2, the difference being only that four SiC wafers are stacked in the graphite crucible, 6H-4HN-6H-4H from top to bottom.

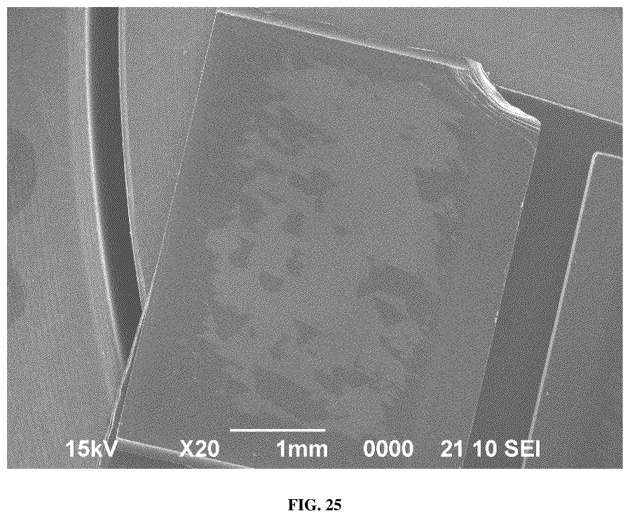

FIG. 25 is the SEM image of the sample obtained in example 16. As can be seen from FIG. 25, the crystal domain width of semiconducting graphene exceeds 200 μm.

Example 17 Semiconducting graphene is grown directly on the Si surface of the SiC substrate using the preparation method of Example 2, the difference being only that five SiC wafers are stacked in the graphite crucible, 6H-4HN-6H-4H-6H from top to bottom.

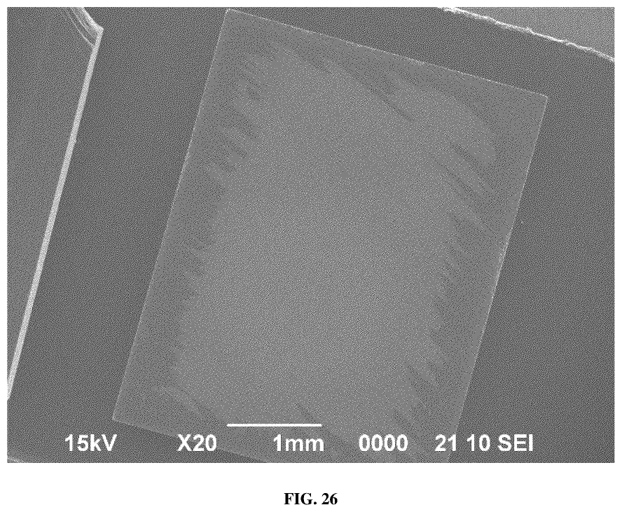

FIG. 26 is the SEM image of the sample obtained in example 17. As can be seen from FIG. 26, the crystal domain width of semiconducting graphene exceeds 200 μm.

Example 18 Semiconducting graphene is grown directly on the Si surface of the SiC substrate using the preparation method of Example 2, the difference being only that six SiC wafers are stacked in the graphite crucible, 6H-4HN-6H-4H-6H-4HN from top to bottom.

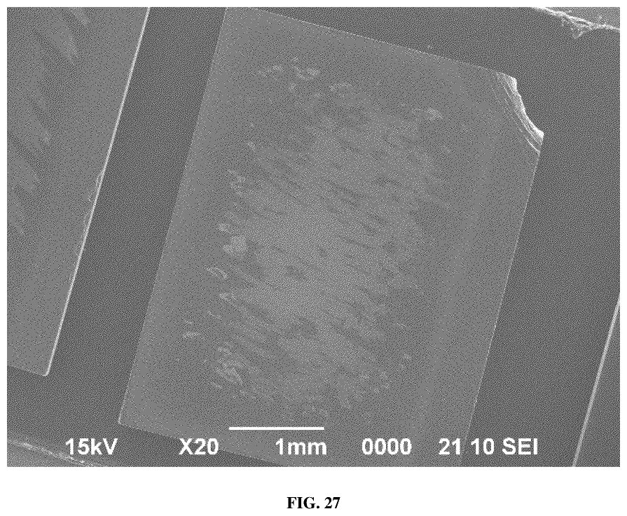

FIG. 27 is the SEM image of the sample obtained in example 18. As can be seen from FIG. 27, the crystal domain width of semiconducting graphene exceeds 200 μm.

This disclosure thoroughly discusses how to increase the domain size of semiconducting graphene and applies large-domain semiconducting graphene to logic devices. Considering that the Si face of ordinary SiC is alternately distributed between plateaus and steps due to the bunching effect, the size of the single crystal is limited. The above examples provide three methods of preparing semiconducting graphene that significantly expand its domain area: firstly, the use of a carbon film-assisted method greatly increases the plateau area, where the carbon-containing polymer-carbon film plays a key role, and the semiconducting graphene prepared by this method has domain sizes reaching 500 μm and mobility over 4500 cm²/(V·s). Secondly, this method realizes the preparation of large single-domain semiconducting graphene on two SiC substrates simultaneously, which improves the utilization rate of SiC and thus increases the yield, becoming a key factor in increasing production capacity in actual industrial production. Thirdly, without using the carbon film-assisted method, only two specifically arranged SiC substrates are needed to prepare large single-domain semiconducting graphene. This method avoids the technical difficulties in the carbon film preparation stage and provides more convenient conditions for industrial applications with domain sizes exceeding 200 μm. Lastly, using a modified graphite crucible, semiconducting graphene with domain sizes over 200 μm is successfully prepared on a single SiC substrate. Therefore, the three methods of preparing semiconducting graphene in this disclosure provide different options for industrial production, allowing flexible choice of preparation methods according to the industry status. This offers an important technical route for the actual application of semiconducting graphene, both in terms of quality and technology, and has great potential value in breaking through technical barriers, increasing production capacity, and utilization.

Additionally, the above examples do not limit the type of crystal form of the silicon carbide substrate, which can be 6H, 4H, 3C, etc., and can also use n-type doped substrates or semi-insulating substrates. This demonstrates that the preparation method of this disclosure has characteristics of universality, simplicity, and flexibility.

Example 19 for the Disclosure of a semiconducting graphene-Quasi-free standing graphene All-Carbon Structure and Its Preparation Method:

### Preparation of Semiconducting Graphene:

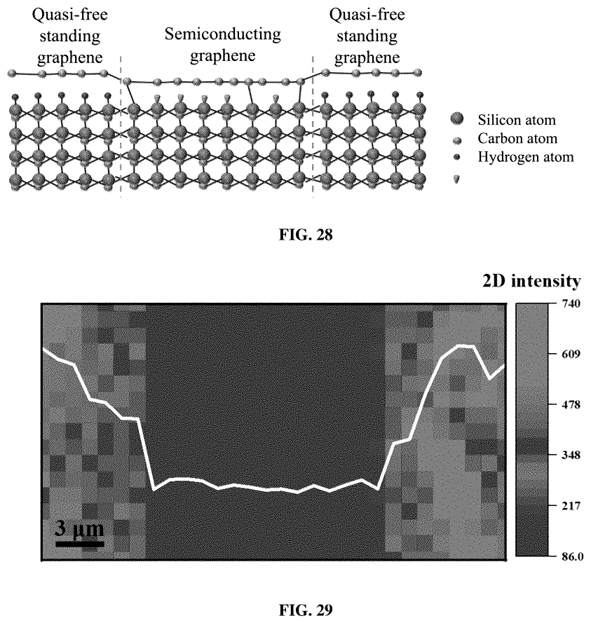

S1. semiconducting graphene is directly grown on the Si face of a SiC substrate, with the following steps:
S11, select two SiC wafers, named SiC substrate A and SiC substrate B;
S12, clean SiC substrates A and B in acetone, anhydrous ethanol, and deionized water using ultrasonics, then dry with N₂;
S13, cover the C-face of SiC wafer A with a carbon film, SiC wafer B remains uncoated; the carbon film can be prepared using high-temperature decomposition, spin-coating, physical vapor deposition, or chemical plating;
S14, place the carbon-coated SiC wafer A and the uncoated SiC wafer B in a standard graphite crucible; specifically, stack the bottom SiC wafer A with its Si-face facing the Si-face of the top SiC wafer B;
alternatively, place uncoated SiC wafers A and B in a standard graphite crucible, with the C-face of SiC wafer A facing the Si-face of SiC wafer B;
alternatively, choose a single SiC wafer and place it in a modified graphite crucible, where the bottom outer surface of the crucible is changed from a curved to a flat surface;
S2, place the graphite crucible with SiC wafer(s) into an induction heating furnace:
S21, maintain the graphite crucible with SiC wafer(s) in a vacuum environment at 900-950° C. for 20-30 minutes;
S22, introduce a flow of 400 sccm Ar gas, maintaining at a constant temperature of 1250-1300° C. for 20-30 minutes;
S23 introduce with a flow of 400 sccm Ar gas, maintaining at 1560-1700° C. for 50-600 minutes.
S3, cool the furnace to obtain semiconducting graphene.
   Preparation of the Semiconducting Graphene-Quasi-Free Standing Graphene all-Carbon Structure:
S4 apply photoresist on the surface of the prepared semiconducting graphene.
S5 pattern the applied photoresist using photolithography; this step is conducted in a photolithography machine;
S6 deposit a layer of Al₂O₃ dielectric on the patterned semiconducting graphene surface using atomic layer deposition;
S7 strip the semiconducting graphene with the dielectric layer in an organic solvent to obtain the patterned dielectric layer, leaving parts of the semiconducting graphene surface covered with the dielectric layer and other parts uncovered;
S8 finally, heat in a hydrogen atmosphere with a flow rate of 80 sccm at 1000° C. for 11 minutes to obtain the semiconducting graphene-quasi-free standing graphene all-carbon structure. In this structure, both the semiconducting graphene and quasi-free standing graphene are single layers, seamlessly overlapping to form a continuous whole, as shown in FIGS. 28 and 29.

### Raman Imaging (FIG. 29):

The Raman image of the quasi-free standing graphene-semiconducting graphene structure prepared in Example 19 clearly shows the distinct boundaries between the quasi-free standing graphene and semiconducting graphene, both of which are uniform without any impurities.

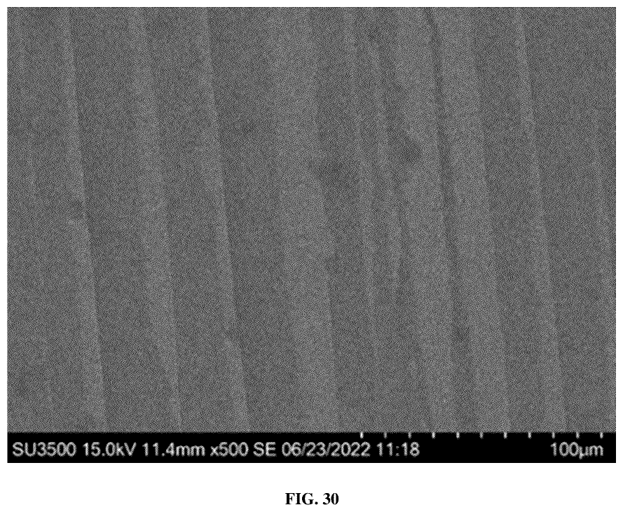

### SEM Imaging (FIG. 30):

The SEM image shows the contrast with the darker areas representing quasi-free standing graphene and the lighter areas representing semiconducting graphene.

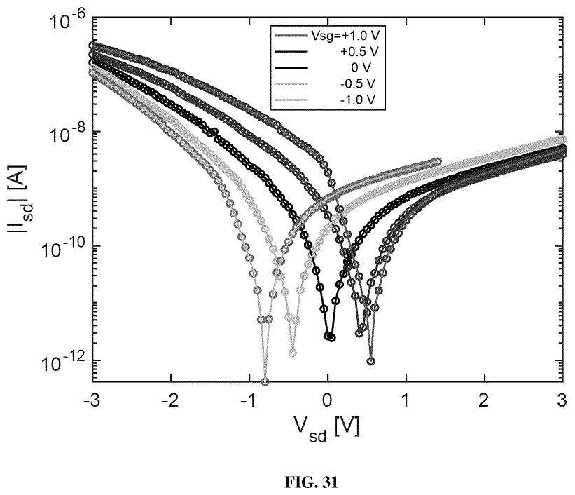

### Device Performance Chart (FIG. 31):

The device achieves an on/off ratio of over 104.

Example 20 The preparation of the semiconducting graphene-quasi-free standing graphene all-carbon structure using the method from Example 19, with the only difference being in step S6, where the deposited dielectric layer is HfO₂. A seamlessly connected quasi-free standing graphene-semiconducting graphene structure is successfully prepared, with high uniformity in all parts.

Example 21 The preparation of the semiconducting graphene-quasi-free standing graphene all-carbon structure using the method from Example 19, with the only difference being in stepS6, where the deposited dielectric layer is Y₂O₃. A seamlessly connected quasi-free standing graphene-semiconducting graphene structure is successfully prepared, with high uniformity in all parts.

Example 22 The preparation of the semiconducting graphene-quasi-free standing graphene all-carbon structure using the method from Example 19, with the only difference being in step S6, where the deposited dielectric layer is SiO₂. A seamlessly connected quasi-free standing graphene-semiconducting graphene structure is successfully prepared, with high uniformity in all parts.

Example 23 The preparation of the semiconducting graphene-quasi-free standing graphene all-carbon structure using the method from Example 19, with the only difference being in step S6, where the deposition method is electron beam evaporation. A seamlessly connected quasi-free standing graphene-semiconducting graphene structure is successfully prepared, with high uniformity in all parts.

Example 24 The preparation of the semiconducting graphene-quasi-free standing graphene all-carbon structure using the method from Example 19, with the only difference being in step S6, where the deposition method is magnetron sputtering. A seamlessly connected quasi-free standing graphene-semiconducting graphene structure is successfully prepared, with high uniformity in all parts.

Example 25 The preparation of the semiconducting graphene-quasi-free standing graphene all-carbon structure using the method from Example 19, with the only difference being in step S8, where the hydrogen gas flow rate is 50 sccm. A seamlessly connected quasi-free standing graphene-semiconducting graphene structure is successfully prepared.

Example 26 The preparation of the semiconducting graphene-quasi-free standing graphene all-carbon structure using the method from Example 19, with the only difference being in step S8, where the hydrogen gas flow rate is 100 sccm. A seamlessly connected quasi-free standing graphene-semiconducting graphene structure is successfully prepared.

Example 27 The preparation of the semiconducting graphene-quasi-free standing graphene all-carbon structure using the method from Example 19, with the only difference being in step S8, where the heating temperature is 500° C. A seamlessly connected quasi-free standing graphene-semiconducting graphene structure is successfully prepared, but the graphene D peak is high, indicating lower quality.

Example 28 The preparation of the semiconducting graphene-quasi-free standing graphene all-carbon structure using the method from Example 19, with the only difference being in step S8, where the heating temperature is 1000° C. A seamlessly connected quasi-free standing graphene-semiconducting graphene structure is successfully prepared.

Example 29 The preparation of the semiconducting graphene-quasi-free standing graphene all-carbon structure using the method from Example 19, with the only difference being in step S8, where the heating time is 5 minutes. A seamlessly connected quasi-free standing graphene-semiconducting graphene structure is successfully prepared, but the graphene D peak is high, indicating poor quality.

Example 30 The preparation of the semiconducting graphene-quasi-free standing graphene all-carbon structure using the method from Example 19, with the only difference being in step S8, where the heating time is 60 minutes. A seamlessly connected quasi-free standing graphene-semiconducting graphene structure is successfully prepared.

Example 31 The preparation of the semiconducting graphene-quasi-free standing graphene all-carbon structure using the method from Example 19, with the only difference being in step S8, where the heating time is 30 minutes. A seamlessly connected quasi-free standing graphene-semiconducting graphene structure is successfully prepared, with high uniformity in all parts.

Example 32 Direct growth of semiconducting graphene on the Si surface of the SiC substrate, with the specific steps as follows:
S1, select two silicon carbide wafers, respectively named as silicon carbide substrate A and silicon carbide substrate B;
S2, clean silicon carbide substrate A and silicon carbide substrate B in acetone, anhydrous ethanol, and deionized water ultrasonically, then dry with N₂;
S3, cover the C-face of silicon carbide wafer A with a carbon film, and silicon carbide wafer B is not coated with a carbon film; the carbon film can be prepared by methods such as high-temperature decomposition, spin-coating, physical vapor deposition, and chemical plating;
S4, place the carbon-coated silicon carbide wafer A and the uncoated silicon carbide wafer B into a standard graphite crucible; specifically, stack the bottom silicon carbide wafer A with its Si-face facing the Si-face of the top silicon carbide wafer B;
S5, place the graphite crucible containing the silicon carbide wafer into an induction heating furnace:
S51, maintaining the graphite crucible in a vacuum environment at 900-950° C. for 20-30 minutes;
S52, introduce with a flow of 400 sccm Ar gas, maintaining a constant temperature of 1250-1300° C. for 20-30 minutes;
S53, introduce with a flow of 400 sccm Ar gas, maintaining at 1560-1700° C. for 50-600 minutes;
S6, after furnace cooling, obtain the semiconducting graphene;

Preparation steps for the semiconducting graphene-quasi-free standing graphene all-carbon structure are as follows: subject the prepared semiconducting graphene to localized laser induction, using a laser power of 520 mJ for 5 minutes, to obtain the semiconducting graphene-quasi-free standing graphene all-carbon structure.

### SEM Image (FIG. 32):

The SEM image from Example 32 shows the prepared quasi-free standing graphene-semiconducting graphene structure, with the darker contrast areas being quasi-free standing graphene and the lighter areas being semiconducting graphene.

Example 33 The preparation of the semiconducting graphene-quasi-free standing graphene all-carbon structure using the method from Example 32, with the only difference being that during the laser induction of the prepared semiconducting graphene, the laser power used is 1200 mJ to obtain the semiconducting graphene-quasi-free standing graphene all-carbon structure.

Example 34 Direct growth of semiconducting graphene on the Si surface of the SiC substrate, with the specific steps as follows:
S1, select two silicon carbide wafers, respectively named as silicon carbide substrate A and silicon carbide substrate B;
S2, clean silicon carbide substrate A and silicon carbide substrate B in acetone, anhydrous ethanol, and deionized water ultrasonically, then dry with N₂;
S3, cover the C-face of silicon carbide wafer A with a carbon film, and silicon carbide wafer B is not coated with a carbon film; the carbon film can be prepared by methods such as high-temperature decomposition, spin-coating, physical vapor deposition, and chemical plating;
S4, place the carbon-coated silicon carbide wafer A and the uncoated silicon carbide wafer B into a standard graphite crucible; specifically, stack the bottom silicon carbide wafer A with its Si-face facing the Si-face of the top silicon carbide wafer B;
S5, place the crucible containing the silicon carbide wafer into an induction heating furnace:
S51, maintaining the crucible in a vacuum environment at 900-950° C. for 20-30 minutes;
S52, introduce with a flow of 400 sccm Ar gas, maintaining a constant temperature of 1250-1300° C. for 20-30 minutes;
S53, introduce with a flow of 400 sccm Ar gas, maintaining at 1560-1700° C. for 50-600 minutes;
S6, after furnace cooling, obtain the semiconducting graphene.

Optionally, S4 is performed as follows: place both uncoated silicon carbide wafer A and silicon carbide wafer B into a standard graphite crucible; specifically, the C-face of silicon carbide wafer A facing the Si-face of silicon carbide wafer B.

Optionally, S4 is performed as follows: choose a single silicon carbide wafer and place it into a modified graphite crucible, with the modification being the change of its bottom outer surface from a curved to a flat surface.

Preparation steps for the semiconducting graphene-quasi-free standing graphene all-carbon structure are as follows: the prepared semiconducting graphene undergoes localized scanning with an atomic force microscope (AFM) tip heating. The tip is an AFM tip, heating temperature is 900° C., heating time is 5 minutes, hydrogen purity is 99.9999%, hydrogen flow rate is 80 sccm, to obtain the semiconducting graphene-quasi-free standing graphene all-carbon structure.

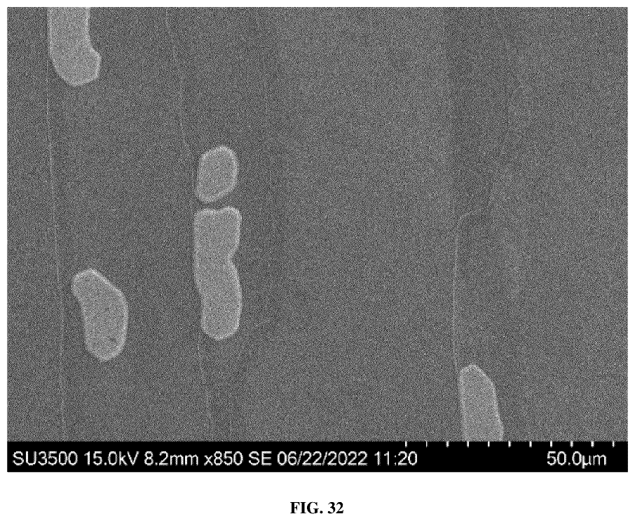

### SEM Image (FIG. 33):

The SEM image from Example 34 shows the prepared quasi-free standing graphene-semiconducting graphene structure, with the darker contrast areas being quasi-free standing graphene and the lighter areas being semiconducting graphene.

Example 35 The preparation of the semiconducting graphene-quasi-free standing graphene all-carbon structure using the method from Example 34, with the only difference being that during the atomic force microscope tip heating of the prepared semiconducting graphene, the tip used is a scanning tunneling microscope tip. A seamlessly connected quasi-free standing graphene-semiconducting graphene structure is successfully prepared, with high uniformity in all parts.

Example 36 The preparation of the semiconducting graphene-quasi-free standing graphene all-carbon structure using the method from Example 34, with the only difference being that during the atomic force microscope tip heating of the prepared semiconducting graphene, the tip used is a NanoFrazor scanning tip. A seamlessly connected quasi-free standing graphene-semiconducting graphene structure is successfully prepared, with high uniformity in all parts.

Example 37 The preparation of the semiconducting graphene—quasi-free standing graphene all-carbon structure using the method from Example 34, with the only difference being that during the atomic force microscope tip heating of the prepared semiconducting graphene, the heating temperature is 700° C. A seamlessly connected quasi-free standing graphene—semiconducting graphene structure is successfully prepared, with high uniformity in all parts.

Example 38 The preparation of the semiconducting graphene—quasi-free standing graphene all-carbon structure using the method from Example 34, with the only difference being that during the atomic force microscope tip heating of the prepared semiconducting graphene, the heating temperature is 500° C. A seamlessly connected quasi-free standing graphene—semiconducting graphene structure is successfully prepared, but the graphene D peak is high, indicating poor quality.

Example 39 The preparation of the semiconducting graphene—quasi-free standing graphene all-carbon structure using the method from Example 34, with the only difference being that during the atomic force microscope tip heating of the prepared semiconducting graphene, the heating time is 1 minute. A seamlessly connected quasi-free standing graphene—semiconducting graphene structure is successfully prepared, with high uniformity in all parts.

Example 40 The preparation of the semiconducting graphene—quasi-free standing graphene all-carbon structure using the method from Example 34, with the only difference being that during the atomic force microscope tip heating of the prepared semiconducting graphene, the hydrogen gas flow rate is 50 sccm. A seamlessly connected quasi-free standing graphene—semiconducting graphene structure is successfully prepared, with high uniformity in all parts.

Example 41 The preparation of the semiconducting graphene—quasi-free standing graphene all-carbon structure using the method from Example 34, with the only difference being that during the atomic force microscope tip heating of the prepared semiconducting graphene, the hydrogen gas flow rate is 100 sccm. A seamlessly connected quasi-free standing graphene—semiconducting graphene structure is successfully prepared, with high uniformity in all parts.

For the disclosure of a large single-domain quasi-free standing graphene and its preparation method, the implementation is as follows:

### Example 42

A preparation method of the large single-domain quasi-free standing grapheme, including following steps:
S1, select two silicon carbide wafers, respectively named as silicon carbide substrate A and silicon carbide substrate B. Perform Chemical Mechanical Polishing (CMP) on both substrates A and B to remove paraffin and thoroughly clean them;
S2, ultrasonically clean silicon carbide substrate A and silicon carbide substrate B in acetone, anhydrous ethanol, and deionized water for 15-30 minutes, then dry with N₂;
S3, cover the C-face of silicon carbide wafer A with a carbon film, while silicon carbide wafer B is not coated with a carbon film. The carbon film can be prepared using high-temperature decomposition, spin-coating, physical vapor deposition, and chemical plating;
S4, place the carbon-coated silicon carbide wafer A and the uncoated silicon carbide wafer B into a standard graphite crucible. Specifically, stack the bottom silicon carbide wafer A with its Si-face facing the Si-face of the top silicon carbide wafer B;
S5 put the crucible containing silicon carbide wafers A and B into an induction heating furnace:
S51, maintain the crucible in a vacuum environment at 900-950° C. for 20-30 minutes;
S52, introduce with a flow of 400 sccm Ar gas, maintaining a constant temperature of 1250-1300° C. for 20-30 minutes;
S53, introduce with a flow of 400 sccm Ar gas, maintaining at 1605° C. for 95 minutes; S6, after furnace cooling, obtain semiconducting graphene;
S7, place the crucible containing the sample into an induction heating furnace under an 80 sccm H2 atmosphere at 1000° C. for 11 minutes for annealing;
S8, after furnace cooling, retrieve the sample.

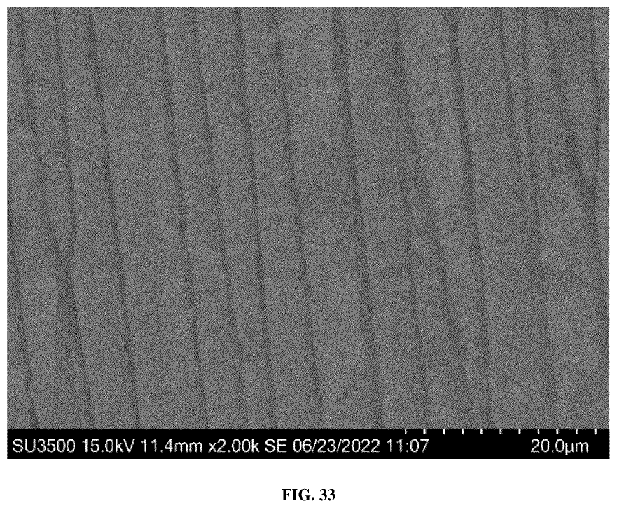

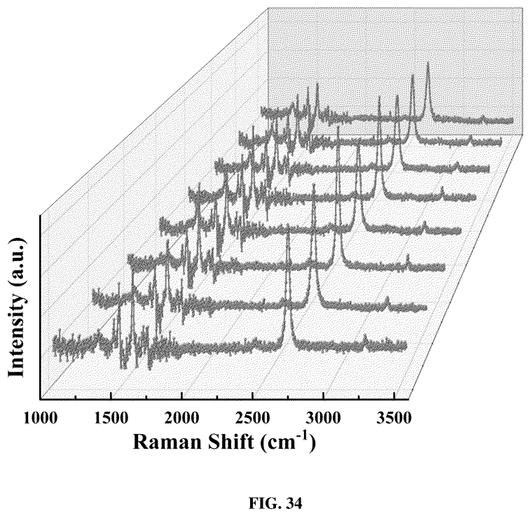

FIG. 34 shows the Raman spectrum characterization of the sample prepared in Example 42. FIG. 35 shows the relationship between the transfer characteristics curve of the sample prepared in Example 42 and temperature, exhibiting a centimeter-level room temperature ballistic transport free path.

### Example 43

A preparation method of the large single-domain quasi-free standing grapheme, including following steps:
S1, select two silicon carbide wafers, respectively named as silicon carbide substrate A and silicon carbide substrate B. Perform Chemical Mechanical Polishing (CMP) on both substrates A and B to remove paraffin and thoroughly clean them;
S2, ultrasonically clean silicon carbide substrate A and silicon carbide substrate B in acetone, anhydrous ethanol, and deionized water for 15-30 minutes, then dry with N₂;
S3, place silicon carbide wafer A and silicon carbide wafer B into a standard graphite crucible, specifically, with the C-face of silicon carbide wafer A facing the Si-face of silicon carbide wafer B;
S4, put the crucible containing the stacked silicon carbide substrates into an induction heating furnace:
S41, maintain the crucible in a vacuum environment at 900-950° C. for 20-30 minutes;
S42, introduce a flow of 400 sccm Ar gas, maintaining a constant temperature of 1250-1300° C. for 20-30 minutes;
S43, introduce a flow of with 400 sccm Ar gas, maintaining at 1610° C. for 105 minutes;
S5, after furnace cooling, obtain the sample;
S6, place the crucible containing the sample into an induction heating furnace under a 90 sccm H2 atmosphere at 900° C. for 15 minutes for annealing;
S7, after furnace cooling, retrieve the sample.

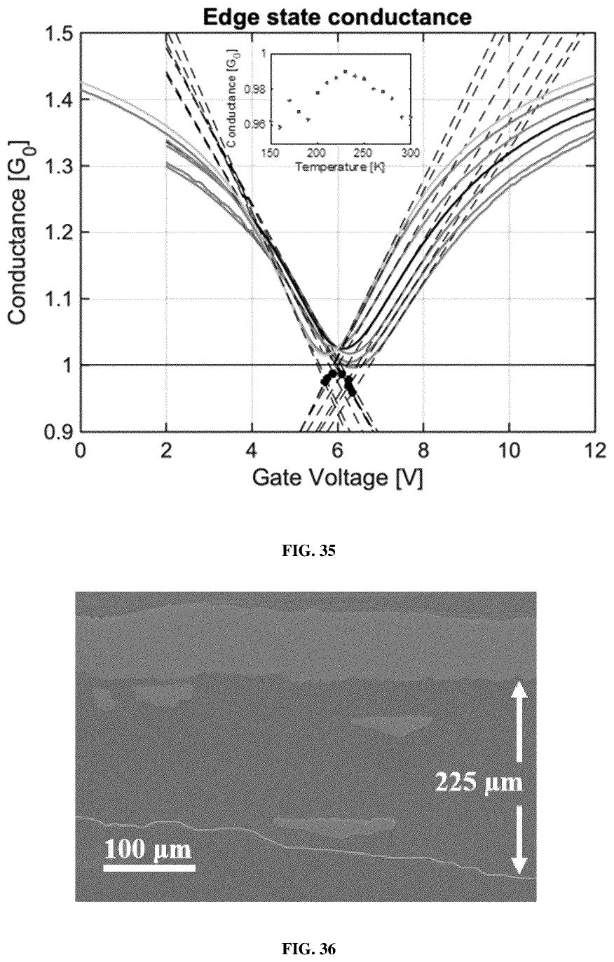

FIG. 36 shows the SEM image of the sample prepared in Example 43.

### Example 44

A preparation method of the large single-domain quasi-free standing grapheme, including following steps:
S1, select a single silicon carbide wafer, perform Chemical Mechanical Polishing (CMP) on it as the silicon carbide substrate to remove paraffin and thoroughly clean it;
S2, ultrasonically clean the silicon carbide substrate in acetone, anhydrous ethanol, and deionized water for 15-30 minutes, then dry with N₂;
S3, place the silicon carbide wafer into a modified graphite crucible, where the bottom outer surface of the crucible is changed from a curved to a flat surface;
S4, put the crucible containing the silicon carbide substrate into an induction heating furnace:
S41, maintain the crucible in a vacuum environment at 900-950° C. for 20-30 minutes;
S42, introduce a flow of 400 sccm Ar gas, maintaining a constant temperature of 1250-1300° C. for 20-30 minutes;
S43, introduce a flow of 400 sccm Ar gas, maintaining at 1700° C. for 80 minutes; S5, after furnace cooling, obtain the sample;
S6, place the crucible containing the sample into an induction heating furnace under a 100 sccm H2 atmosphere at 1100° C. for 30 minutes for annealing;
S7, after furnace cooling, retrieve the sample.

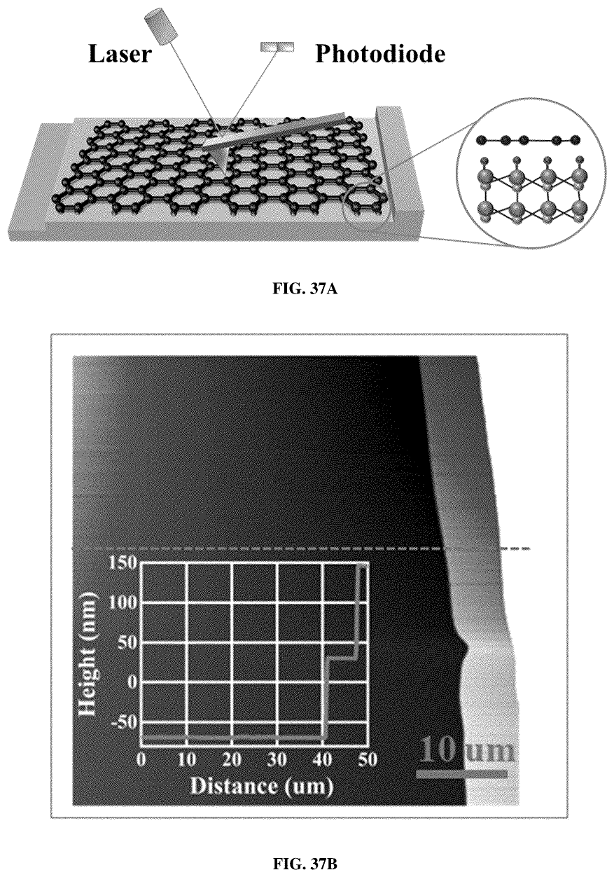

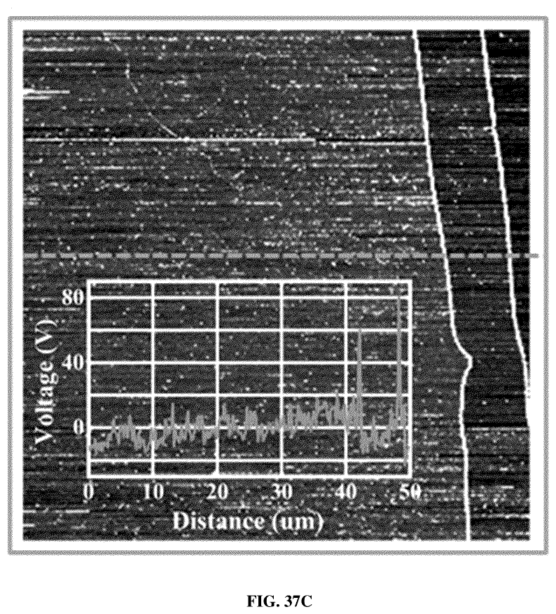

FIGS. 37A, 37B, and 37C show the AFM morphology and Lateral Force Microscopy (LFM) image of the sample prepared in Example 44. FIG. 37A is a schematic of AFM scanning of the sample; FIG. 37B is a morphology image, the inset shows the data of random line scanning; and FIG. 37C is a Lateral Force Microscopy (LFM) image, the inset shows the data of random line scanning.

Example 45 Prepare samples following the steps in Example 42, with the only difference being that inS6, the heating time is 40 minutes.

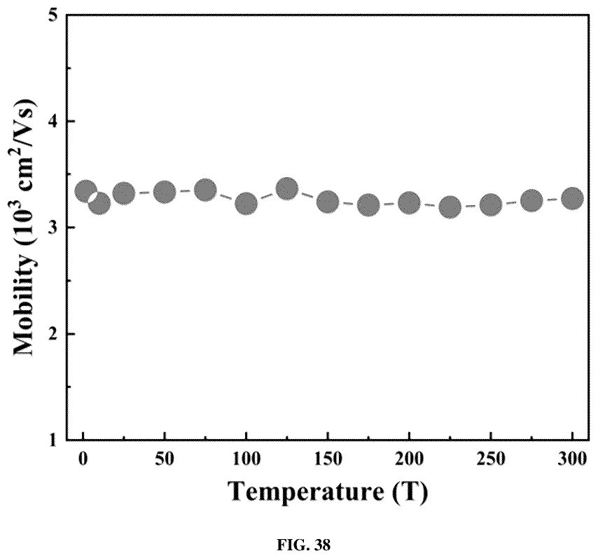

FIG. 38 shows the relationship between the mobility and temperature of the sample prepared in Example 45.

Example 46 Prepare samples following the steps in Example 42, with the only difference being that in S6, the heating time is 80 minutes.

Example 47 Prepare samples following the steps in Example 42, with the only difference being that in S6, the heating time is 60 minutes.

Example 48 Prepare samples following the steps in Example 42, with the only difference being that in S6, the heating temperature is 1200° C.

Example 49 Prepare samples following the steps in Example 42, with the only difference being that in S6, the heating temperature is 1300° C.

Example 50 Prepare samples following the steps in Example 42, with the only difference being that in S6, the hydrogen gas flow rate is 90 sccm.

Example 51 Prepare samples following the steps in Example 42, with the only difference being that in S6, the hydrogen gas flow rate is 50 sccm.

This disclosure discusses in detail the preparation of quasi-free standing graphene directly on an insulating substrate using hydrogen intercalation. Considering that the mobility of typical graphene on Si faces is low due to substrate-induced n-type doping, steps and the presence of bi/tri-layer graphene stripes at step edges as scattering sources. Although it is easy to prepare monolayer graphene on the Si face of SiC, the graphene on Si face is not continuous but mixed with bi-layer or tri-layer graphene stripes, and their domain size (crystal domain width) does not exceed 10 μm. Therefore, based on the growth of large-area single-domain semiconducting graphene, further hydrogen intercalation achieves domain widths exceeding 500 μm and room temperature mobility reaching 3300 cm²/V·s, which is more than three times that of traditional graphene on Si faces.

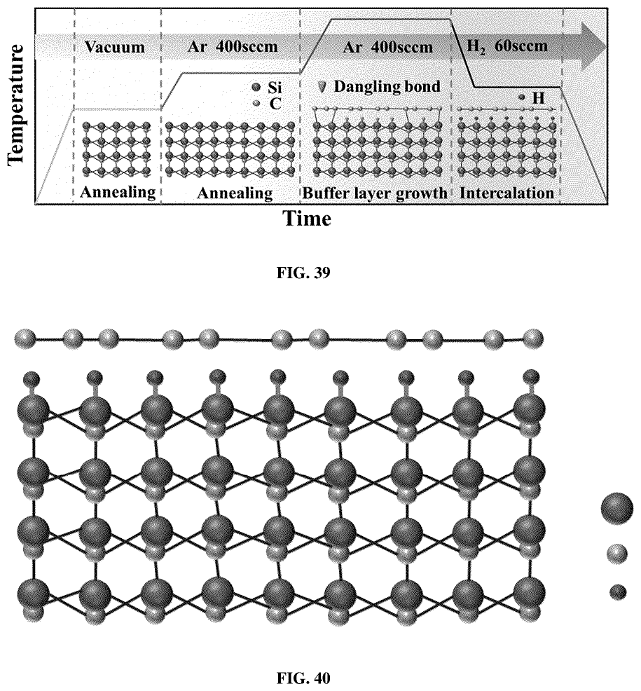

FIG. 39 shows the growth process of quasi-free standing graphene in Example 42. FIG. 40 shows the atomic structure (side view) of quasi-free standing graphene in Example 42, where yellow solid spheres represent Si atoms, grey solid spheres represent C atoms, and blue solid spheres represent H atoms.

To further characterize the uniformity of the single-domain quasi-free standing graphene, it was characterized by Raman, which shows high uniformity of the quasi-free standing graphene, as shown in FIG. 34. FIG. 36 shows the SEM image of the quasi-free standing graphene, revealing widths exceeding 200 μm. Additionally, AFM was used to characterize the uniformity of the quasi-free standing graphene. Both the morphology and lateral force images show high uniformity, as shown in FIGS. 37A-37C. FIG. 38 shows the relationship between the Hall mobility and temperature of the quasi-free standing graphene, indicating no dependence of mobility on temperature. FIG. 35 shows the variation of the transfer characteristics with temperature for the quasi-free standing graphene, showing that the residual resistance is around 1G0 (G0 is the quantum conductance), resulting in the quasi-free standing graphene having a centimeter-level room temperature ballistic transport mean free path.

The uniformity, crystal domain quality, domain width and length, mobility, and ballistic mean free path of large-area single-domain quasi-free standing graphene samples prepared in other examples within the scope of protection of this disclosure were studied, yielding results similar to those described above.

The above-described implementations, only as the preferred examples of the present disclosure, are intended to illustrate the present disclosure, but not to limit the present disclosure, and any modifications, equivalent replacements, improvements, etc. made within the spirit of the present disclosure and the scope of protection of the claims fall within the scope of protection of the present disclosure.

What is claimed is:

1. A large single-crystal semiconducting graphene, wherein the semiconducting graphene directly grown on the silicon face of a silicon carbide substrate, and the semiconducting graphene is single-layered, uniformly grown, with crystal domain widths reaching up to 500 micrometers and lengths on the order of sub-millimeters; the room temperature mobility of the semiconducting graphene is capable of reaching 5000 cm²/(V·s).

2. The large single-crystal semiconducting graphene according to claim 1, wherein the semiconducting graphene exhibits a graphene lattice structure and forms bonds with the SiC substrate, resulting in a bandgap.

3. The large single-crystal semiconducting graphene according to claim 1, wherein the crystal domain width of the semiconducting graphene is greater than 200 micrometers.

4. The large single-crystal semiconducting graphene according to claim 1, wherein the silicon carbide substrate is of 6H, 4H, or 3C polytype.

5. A method for preparing the large single-crystal semiconducting graphene according to claim 1, the preparation method includes the following steps:
S1, pre-treat several SiC substrates, wherein after pre-treatment, a carbon film is prepared on the C-face of one of the SiC substrates;
S2, stack the several SiC substrates and place them in a crucible with the Si-faces of the SiC substrates facing each other;
S3, anneal the crucible with the stacked SiC substrates under vacuum conditions to clean the SiC substrates;
S4, heat the crucible with the stacked SiC substrates in inert gas atmosphere;
S5, further heat the crucible with the stacked SiC substrates in inert gas atmosphere to grow semiconducting graphene, obtain semiconducting graphene on the SiC substrates.

6. The method according to claim 5, wherein in step S1, the carbon film is selected from one of photoresist, PMMA, and amorphous carbon, prepared by any one of the following steps:
high-temperature decomposition, physical vapor deposition, chemical deposition, or coating.

7. The method according to claim 5, wherein the annealing temperature under vacuum conditions in step (3) S3 ranges from 900° C. to 950° C., and the time ranges from 20 minutes to 30 minutes.

8. The method according to claim 5, wherein the temperature for heating the SiC substrates in inert gas atmosphere in step (4) S4 ranges from 1250° C. to 1300° C., and the heating time ranges from 20 minutes to 30 minutes.

9. The method according to claim 5, wherein the temperature for further heating in inert gas atmosphere in step (5) S5 ranges from 1560° C. to 1700° C., and the time is 50 minutes to 600 minutes.

10. A method for preparing the large single-crystal semiconducting graphene according to claim 1, wherein the preparation method includes the following steps:
S1, pre-treat several SiC substrates;
S2, stack the several SiC substrates and place them in a crucible with the C-face of one SiC substrate facing the Si-face of the other;
S3, anneal the crucible with the stacked SiC substrates under vacuum conditions to clean the SiC substrates;
S4, heat the crucible with the stacked SiC substrates in inert gas atmosphere;
S5, further heat the crucible with the stacked SiC substrates in inert gas atmosphere to grow semiconducting graphene, obtain semiconducting graphene on one SiC substrate.

11. The method according to claim 10, wherein in step S3, the annealing temperature under vacuum conditions preferably ranges from 900° C. to 950° C., and the time ranges from 20 minutes to 30 minutes.

12. The method according to claim 11, wherein the temperature for heating the SiC substrates in inert gas atmosphere in step S4 ranges from 1250° C. to 1300° C., and the heating time ranges from 20 minutes to 30 minutes.

13. The method according to claim 11, wherein the temperature for further heating in inert gas atmosphere in step S5 ranges from 1560° C. to 1700° C., and the time ranges from 50 minutes to 600 minutes.

14. A method for preparing the large single-crystal semiconducting graphene according to claim 1, wherein the preparation method includes the following steps:
S1, pre-treat SiC substrates and place it in a modified crucible with the bottom outer surface of the crucible being flat;
S2, anneal the modified crucible with the stacked SiC substrate under vacuum conditions to clean the SiC substrate;
S3, heat the modified crucible with the stacked SiC substrate in inert gas atmosphere;
S4, further heat the modified crucible with the stacked SiC substrate in inert gas atmosphere to grow semiconducting graphene, obtain semiconducting graphene on the SiC substrate.

15. The method according to claim 14, wherein in step S1, the pre-treatment involves mechanical and chemical polishing of the SiC substrate, followed by ultrasonic cleaning and gas drying.

16. The method according to claim 14, wherein in step S3, the annealing temperature under vacuum conditions preferably ranges from 900° C. to 950° C., and the time ranges from 20 minutes to 30 minutes.

17. The method according to claim 14, wherein the temperature for heating the SiC substrate in inert gas atmosphere in step S4 ranges from 1250° C. to 1300° C., and the heating time ranges from 20 minutes to 30 minutes.

18. The method according to claim 14, wherein the temperature for further heating in inert gas atmosphere in step S5 ranges from 1560° C. to 1700° C., and the time ranges from 50 minutes to 600 minutes.

19. A semiconducting graphene-quasi-free standing graphene all-carbon structure, comprising a silicon carbide substrate, a Si-face of the substrate is prepared with the large single-crystal semiconducting graphene according to claim 1 and quasi-free standing graphene; both the semiconducting graphene and quasi-free standing graphene are single-layered, forming a seamlessly overlapped continuous entity on the plane; and the quasi-free standing graphene being capable of serving as the electrode part, while the semiconducting graphene is functioned as the channel material.

20. A method for preparing the semiconducting graphene-quasi-free standing graphene all-carbon structure according to claim 19, wherein the preparation method includes the following steps:
S1 prepare the semiconducting graphene on the surface of the SiC substrate;
S2 in a localized area of the semiconducting graphene obtained in step S1, prepare quasi-free standing graphene using one of the following methods: hydrogen intercalation, electron beam lithography, focused ion beam, laser-induced, or atomic force microscope tip heating.

21. The method according to claim 20, wherein when preparing the quasi-free standing graphene using hydrogen intercalation, the following steps are adopted:
S21, spin-coat photoresist on the surface of the semiconducting graphene;
S22, use photolithography to pattern the spun photoresist;
S23, deposit a dielectric layer on the patterned semiconducting graphene surface;
S24, peel off the photoresist-covered semiconducting graphene to obtain the patterned dielectric layer; partially cover the surface of the semiconducting graphene with the dielectric layer and leave the rest uncovered;
S25, heat the semiconducting graphene covered with the patterned dielectric layer in a hydrogen atmosphere to obtain the semiconducting graphene-quasi-free standing graphene all-carbon structure.

22. The method according to claim 21, wherein the dielectric layer is made of Al₂O₃, HfO₂, Y₂O₃, or SiO₂.

23. The method according to claim 21, wherein the deposition methods for the dielectric layer include atomic layer deposition, electron beam evaporation, and magnetron sputtering.

24. The method according to claim 21, wherein in step S25, the hydrogen flow rate preferably ranges from 50 sccm to 100 sccm.

25. The method according to claim 21, wherein in step S25, the heating temperature preferably ranges from 500° C. to 1100° C.

26. The method according to claim 21, wherein in step S25, the heating time preferably ranges from 5 minutes to 60 minutes.

27. The method according to claim 21, when preparing quasi-free standing graphene using laser-induced methods, a laser power of 520-1500 mJ is adopted; when using atomic force microscopy tip heating, the tip is selected from one of atomic force microscopy tips, scanning tunneling microscopy tips, and multiple-probe scanning tips; and the heating temperature of the atomic force microscopy tip ranges from 500° C. to 900° C.

28. An ultra-large single-crystal quasi-free standing graphene, includes a silicon carbide (SIC) substrate with a uniformly grown quasi-free standing graphene on the Si-face of the SiC substrate; the quasi-free standing graphene is a single layer, with crystal domain widths of up to 500 micrometers and lengths in the sub-centimeter range; the quasi-free standing graphene exhibits a centimeter-scale ballistic transport mean free path at room temperature.

29. The ultra-large single-crystal quasi-free standing graphene according to claim 28, wherein the crystal domain width of the semiconducting graphene is greater than 200 micrometers, and the room temperature mobility of the quasi-free standing graphene can reach 3300 cm²/(V·s).

30. The ultra-large single-crystal quasi-free standing graphene according to claim 28, wherein the quasi-free standing graphene is not bonded to the SiC substrate and exhibits semimetallic properties.

31. The ultra-large single-crystal quasi-free standing graphene according to claim 28, wherein to prepare the quasi-free standing graphene using hydrogen intercalation, the semiconducting graphene is heated in a hydrogen atmosphere at a temperature ranges from 900° C. to 1300° C. for a duration of 10 to 80 minutes.

32. The ultra-large single-crystal quasi-free standing graphene according to claim 31, wherein the hydrogen gas flow rate during hydrogen intercalation is preferably between 50 and 100 sccm.
